(19) United States
(12) Patent Application Publication
(10) Pub. No.: US 2007/0259207 A1
(43) Pub. Date: Nov. 8, 2007

(54) METAL COMPLEX, LIGHT-EMITTING DEVICE, AND IMAGE DISPLAY APPARATUS

(75) Inventors: MASASHI HASHIMOTO, TOKYO (JP); TAKAO TAKIGUCHI, TOKYO (JP); SHINJIRO OKADA, KAMAKURA-SHI (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 11/741,948

(22) Filed: Apr. 30, 2007

(30) Foreign Application Priority Data
May 8, 2006 (JP) 2006-129296

(51) Int. Cl. H01L 51/54; C09K 11/06

(52) U.S. Cl. 428/690; 428/917; 313/504; 313/506; 257/E51.044; 546/4; 546/10; 548/103; 548/402

(57) ABSTRACT

There are provided a metal complex which is used as a novel compound for an organic EL device and an organic light-emitting device which uses the metal complex and has an optical output with high efficiency and high luminance. The novel metal complex has, in a partial structure thereof, a non-aromatic ring structure containing at least one olefin and an alkylene group containing at least one F atom, and an unsaturated heterocyclic ring structure containing at least one nitrogen atom. The organic light-emitting device includes a pair of electrodes including an anode and a cathode and at least one layer including an organic compound and interposed between the pair of electrodes, in which the layer including the organic compound contains a metal complex represented by the following structural formula.

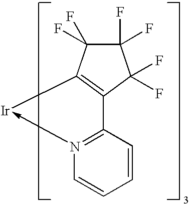

### BACKGROUND OF THE INVENTION

1. Field of the Invention

The present invention relates to a novel metal complex for a light-emitting device, an organic light-emitting device (also referred to as “organic electroluminescent device” or “organic EL device”) for use in, for example, a surface light source or a flat panel display, and an image display apparatus.

2. Description of the Related Art

In an old example of an organic light-emitting device, a voltage has been applied to an anthracene evaporated film to emit light (Thin Solid Films, 94 (1982), 171). However, in recent years, the organic light-emitting device has advantages such as ease of large-area production compared with inorganic light-emitting devices, obtainability of desired color emission by the development of various new materials, and low voltage drivability. Furthermore, active research including material development is being conducted for the development of the organic light-emitting device as a light-emitting device having high-speed responsibility and high efficiency.

For example, as detailed in Macromol. Symp. 125, 1-48 (1997), an organic EL device is generally structured to have two (upper and lower) electrodes formed on a transparent substrate and an organic substance layer including a light-emitting layer formed between the electrodes.

In addition, investigation has been recently made into a device using not only conventional light emission utilizing fluorescence upon transition from singlet exciton to ground state but also phosphorescence via triplet exciton as typified by D. F. O'Brien et al, “Improved energy transfer in electrophosphorescent device”, Applied Physics Letters, Vol. 74, No. 3, p. 422 (1999) and M. A. Baldo et al, “Very high-efficiency green organic light-emitting devices based on electrophosphorescence”, Applied Physics Letters, Vol. 75, No. 1, p. 4 (1999). In these articles, an organic layer having a four-layer structure is mainly used. The structure is composed of a hole-transporting layer, a light-emitting layer, an exciton diffusion-prevention layer, and an electron-transporting layer stacked in the mentioned order from an anode side. The materials used are carrier transporting materials and a phosphorescent material Ir(ppy)₃ shown below.

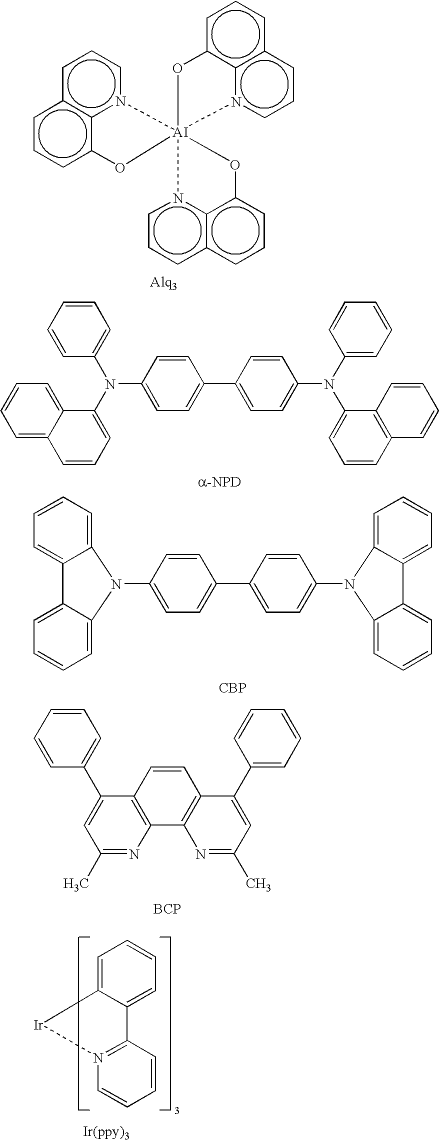

Further, emission of a light from ultraviolet to infrared region can be performed by changing the kind of a fluorescent organic compound. In these days, research has been actively conducted on various compounds.

In addition to organic light-emitting devices using such low-molecular materials as those described above, a group of the University of Cambridge has reported organic light-emitting devices using conjugate polymers (Nature, 347, 539 (1990)). This report has confirmed that light emission can be obtained by a single layer by forming polyphenylene vinylene (PPV) in a film shape by use of a coating system.

As described above, recent progress of an organic light-emitting device is remarkable, and is characterized in that a highly responsive, thin, and lightweight light-emitting device that can be driven at a low applied voltage and provides a high luminance and a variety of emission wavelengths can be made, which suggests the applicability to a wide variety of uses.

However, at present, an optical output of a higher luminance and a higher conversion efficiency have been required. In addition, there still remain a large number of problems in terms of durability such as a change over time during long-term use and degradation due to an atmospheric gas containing oxygen or to moisture. Furthermore, light emission of blue, green and red colors having a high color purity is necessary when application to a full-color display or the like is attempted. However, those problems have not been sufficiently solved yet.

In addition, a large number of aromatic compounds and condensed polycyclic aromatic compounds have been studied as fluorescent organic compounds used for an electron-transporting layer, a light-emitting layer, and the like. However, it is difficult to say that a compound sufficiently satisfying the emission luminance and durability requirements has been already obtained.

Examples of patent documents concerning the application of a metal complex compound related to the present invention to an organic EL device include WO 01/072927, Japanese Patent Application Laid-Open Nos. 2002-226495, 2003-73387, and 2004-503059. None of those documents discloses the metal complex of the present invention which is a metal complex having, in a partial structure thereof, a non-aromatic ring structure containing at least one olefin and at least one F atom, and an unsaturated heterocyclic ring structure containing at least one nitrogen atoms.

### SUMMARY OF THE INVENTION

The present invention provides a novel metal complex for an organic EL device having, in a partial structure thereof, a non-aromatic ring structure containing at least one olefin and an alkylene group containing at least one F atom, and an unsaturated heterocyclic ring structure containing at least one nitrogen atom.

The present invention also provides an organic light-emitting device using the metal complex, having an optical output with high efficiency and high luminance, and having high durability. The present invention further provides an organic light-emitting device that can easily be produced at a relatively low cost.

The present invention also provides an image display apparatus using the organic light-emitting device.

In the present invention, a novel metal complex is used in an organic light-emitting device.

According to an aspect of the present invention, there is provided a metal complex including a partial structure represented by the following general formula (1):

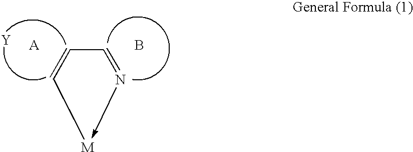

wherein a ring structure A is a non-aromatic cyclic group which includes a carbon atom bonded to M and at least one olefin structure and may have a substituent; Y represents an alkylene group which includes 2 to 6 carbon atoms and at least one F atom in which one methylene group or two non-adjacent methylene groups of the alkylene group may be replaced by —O—, —CO—, —CO—O—, —O—CO—, —S—, —CR₁═CR₂—, or —NR₃— where R₁, R₂, and R₃ may each be substituted with a hydrogen atom, a linear or branched alkyl group having 1 to 10 carbon atoms in which a hydrogen atom of the alkyl group may be substituted with a fluorine atom, and in which a hydrogen atom of the alkylene group may be substituted with a linear or branched alkyl group having 1 to 10 carbon atoms in which a hydrogen atom of the alkyl group may be substituted with a fluorine atom, or with a fluorine atom; a ring B is a cyclic group which has a nitrogen atom bonded to M and may have a substituent selected from a halogen atom, a nitro group, an aromatic ring group which may have a substituent selected from a halogen atom, or a linear or branched alkyl group having 1 to 20 carbon atoms in which one methylene group or two or more non-adjacent methylene groups of the alkyl group may each be replaced by —O—, —S—, —CO—, —CO—O—, —O—CO—, —CH═CH—, or —C≡C— and in which a hydrogen atom of the alkyl group may be substituted with a fluorine atom, a disubstituted amino group, a trialkylsilyl group having 1 to 8 carbon atoms, or a linear or branched alkyl group having 1 to 20 carbon atoms in which one methylene group or two or more non-adjacent methylene groups of the alkyl group may each be replaced by —O—, —S—, —CO—, —CO—O—, —O—CO—, —CH═CH—, or —C≡C—, and in which a hydrogen atom of the alkyl group may be substituted with a fluorine atom; and M represents Ir, Pt, Rh, or Ru.

In addition, more specifically, according to the aspect of the present invention, the metal complex is represented by the following general formula (2):

MLₘL′ₙ (2)

wherein L and L′ represent bidentate ligands different from each other, m represents 1, 2, or 3, n represents 0, 1, or 2 with the proviso that m+n represents 2 or 3, a partial structure MLₘ is represented by the following general formula (3), and a partial structure ML′ₙ is represented by the following general formula (4), (5), or (6):

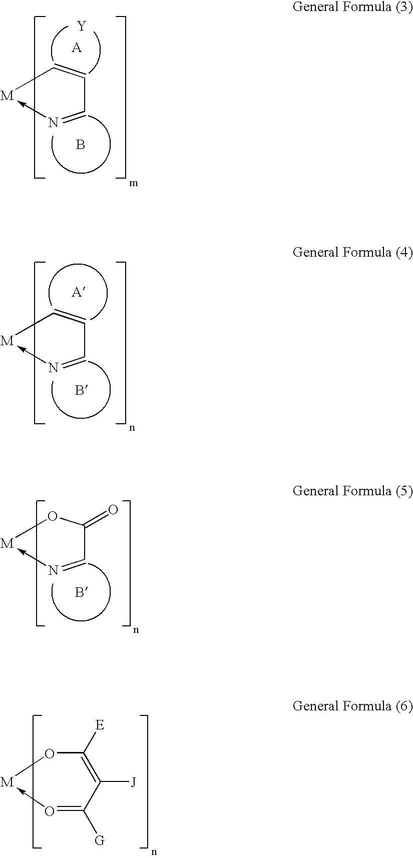

A, B, and Y are each as defined above for the general formula (1); N represents a nitrogen atom, A′ represents a cyclic group which is bonded to a metal atom M through a carbon atom and may have a substituent, B′ represents a cyclic group which is bonded to the metal atom M through a nitrogen atom and may have a substituent, and A′ and B′ are covalently bonded; E and G each represent a linear or branched alkyl group having 1 to 20 carbon atoms in which one methylene group or two or more non-adjacent methylene groups of the alkyl group may each be replaced by —O—, —S—, —CO—, —CO—O—, —O—CO—, —CH═CH—, or —C≡C— and in which a hydrogen atom of the alkyl group may be replaced by a fluorine atom, or an aromatic ring group which may have a substituent selected from a halogen atom, a cyano group, a nitro group, a trialkylsilyl group in which the alkyl groups are each independently a linear or branched alkyl group having 1 to 8 carbon atoms, or a linear or branched alkyl group having 1 to 20 carbon atoms in which one methylene group or two or more non-adjacent methylene groups of the alkyl group may each be replaced by —O—, —S—, —CO—, —CO—O—, —O—CO—, —CH═CH—, or —C≡C— and in which a hydrogen atom of the alkyl group may be substituted with a fluorine atom; J represents a hydrogen atom, a halogen atom, a linear or branched alkyl group having 1 to 20 carbon atoms in which one methylene group or two or more non-adjacent methylene groups may each be replaced by —O—, —S—, —CO—, —CO—O—, —O—CO—, —CH═CH—, or —C≡C— and in which a hydrogen atom of the alkyl group may be substituted with a fluorine atom, or an aromatic ring group which may have a substituent selected from a halogen atom, a cyano group, a nitro group, a trialkylsilyl group in which the alkyl groups are each independently a linear or branched alkyl group having 1 to 8 carbon atoms, or a linear or branched alkyl group having 1 to 20 carbon atoms in which one methylene group or two or more non-adjacent methylene groups may each be replaced by —O—, —S—, —CO—, —CO—O—, —O—CO—, —CH═CH—, or —C≡C— and in which a hydrogen atom of the alkyl group may be substituted with a fluorine atom; and M represents Ir, Pt, Rh, or Ru.

According to the aspect of the present invention, in the metal complex, M preferably represents Ir.

In addition, according to another aspect of the present invention, there is provided a light-emitting device including at least one organic compound layer including a layer containing any one of the above-mentioned metal complexes.

In the present invention, the layer containing the metal complex is preferably a light-emitting layer.

Further, the layer containing the metal complex is preferably a hole-transporting layer.

Moreover, the layer containing the metal complex is preferably an electron-transporting layer.

Further, the light-emitting layer preferably contains a plurality of phosphorescent materials.

In addition, according to still another aspect of the present invention, there is provided an organic light-emitting device including two opposing electrodes and the layer containing the above-mentioned metal complex, the layer being interposed between the two opposing electrodes, in which light is emitted by applying a voltage between the electrodes.

In addition, according to yet another aspect of the present invention, there is provided an image display apparatus including the above-mentioned organic light-emitting device and a unit for supplying an electrical signal to the organic light-emitting device.

The organic light-emitting device using the metal complex of the present invention, especially, the organic light-emitting device using the metal complex as a light-emitting material for its light-emitting layer has an optical output with high efficiency and high luminance, has high durability, and can be easily produced at a relatively low cost.

According to the present invention, there can be provided a novel metal complex for an organic EL device having, in a partial structure thereof, a non-aromatic ring structure containing at least one olefin and an alkylene group containing at least one F atom, and an unsaturated heterocyclic ring structure containing at least one nitrogen atom.

In addition, according to the present invention, there can be provided an organic light-emitting device using the metal complex, having an optical output with high efficiency and high luminance, and having high durability. Further, according to the present invention, there can be provided an organic light-emitting device that can be easily produced at a relatively low cost.

In addition, according to the present invention, there can be provided an image display apparatus using the organic light-emitting device.

Further features of the present invention will become apparent from the following description of exemplary embodiments with reference to the attached drawings.

### BRIEF DESCRIPTION OF THE DRAWINGS

FIG. 1 is a schematic cross-sectional view illustrating an example of an organic EL device of the present invention.

FIG. 2 is a schematic cross-sectional view illustrating another example of the organic EL device of the present invention.

FIG. 3 is a schematic cross-sectional view illustrating still another example of the organic EL device of the present invention.

FIG. 4 is a schematic perspective partial cut-away view illustrating an example of a constitution of a panel provided with an organic EL device and a driving unit.

FIG. 5 is a diagram of pixel circuit of a panel.

FIG. 6 is a schematic diagram illustrating an example of a cross-sectional structure of a TFT substrate which is used in the present invention.

### DESCRIPTION OF THE EMBODIMENTS

First, the metal complex of the present invention will be described.

The metal complex of the present invention has, in a partial structure represented by the following general formula (1), a non-aromatic ring structure (A) containing at least one olefin and an alkylene group containing at least one F atom, and an unsaturated heterocyclic ring structure (B) containing at least one nitrogen atom

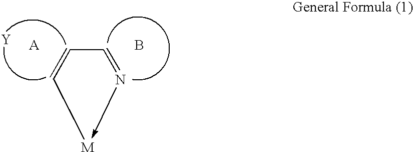

In the formula, the ring structure A is a non-aromatic ring structure which has a carbon atom bonded to M, has at least one olefin structure and may have a substituent.

Specific examples of the substituent which the ring structure A may have are shown below. However, these examples are merely representative examples, and the present invention is not limited thereto.

Examples of the halogen atom include fluorine, chlorine, bromine, and iodine. When a light-emitting device is produced by a vacuum vapor deposition method, fluorine which can be expected to improve the sublimation property is preferably used.

Examples of the linear or branched alkyl group include a methyl group, an ethyl group, a normal propyl group, an isopropyl group, a normal butyl group, a tertiary butyl group, an octyl group, a cyclohexyl group, a methoxy group, and a trifluoromethyl group.

From the viewpoints of conductive property and glass transition temperature, a methyl group, a tertiary-butyl group, a cyclohexyl group and a trifluoromethyl group are preferable; a methyl group, a tertiary-butyl group, and a trifluoromethyl group are more preferable; and a methyl group and a trifluoromethyl group are still more preferable.

Examples of the substituted amino group include a dimethylamino group, a diethylamino group, a dibenzylamino group, a diphenylamino group, a ditolylamino group, and a dianisolylamino group. From the viewpoints of conductive property and glass transition temperature, a dimethylamino group, a diphenylamino group, and a ditolylamino group are preferable, and a diphenylamino group and a ditolylamino group are more preferable.

Examples of the heterocyclic group and the aryl group which may have a substituent include a phenyl group, a biphenyl group, a terphenyl group, a fluorenyl group, a naphthyl group, a thienyl group, a pyrrolyl group, a pyridyl group, a pyrazyl group, a pyrimidyl group, a pyridazinyl group, a quinolinyl group, an isoquinolinyl group, a phenanthridinyl group, a carbazolyl group, a benzoimidazolyl group, and a benzothiazolyl group.

Y represents an alkylene group having 2 to 6 carbon atoms and containing at least one F atom in which one methylene group or two non-adjacent methylene groups of the alkylene group may each be replaced by —O—, —CO—, —CO—O—, —O—CO—, —S—, —CR₁═CR₂—, or —NR₃— where R₁, R₂ and R₃ may each be substituted with a hydrogen atom or a linear or branched alkyl group having 1 to 10 carbon atoms in which a hydrogen atom of the alkyl group may be substituted with a fluorine atom, and in which a hydrogen atom of the alkylene group may be substituted with a linear or branched alkyl group having 1 to 10 carbon atoms in which a hydrogen atom of the alkyl group may be substituted with a fluorine atom, or with a fluorine atom.

Y preferably represents an alkylene group having 2 to 6 carbon atoms, or more preferably represents an alkylene group having 3 or 4 carbon atoms from the viewpoint of making the molecular structure more rigid. This is because making the molecular structure more rigid is considered to suppress a structural change in an excited state, and therefore because an improvement in emission efficiency can be expected.

A unit which constitutes the alkylene group is preferably —CR₄R₅— wherein R₄ and R₅ each preferably represent a hydrogen atom, a halogen atom, or a linear or branched alkyl group having 1 to 10 carbon atoms in which a hydrogen atom of the alkyl group may be substituted with a fluorine atom, more preferably a hydrogen atom, a fluorine atom, a methyl group, a tertiary butyl group, or a trifluoromethyl group, or still more preferably a fluorine atom, a hydrogen atom, or a trifluoromethyl group, —O—, —CR₁═CR₂—, —NR₃— wherein R₁, R₂ and R₃ each preferably represent a hydrogen atom, or a linear or branched alkyl group having 1 to 10 carbon atoms in which a hydrogen atom of the alkyl group may be substituted with a fluorine atom, more preferably a methyl group, a tertiary butyl group, or a trifluoromethyl group, or still more preferably a methyl group, or a trifluoromethyl group, —CO—O—, —C—CO—, or —CO—.

The unit is more preferably —CR₄R₅— wherein R₄ and R₅ each preferably represent a hydrogen atom, a halogen atom, or a linear or branched alkyl group having 1 to 10 carbon atoms in which a hydrogen atom of the alkyl group may be substituted with a fluorine atom, more preferably a hydrogen atom, a fluorine atom, a methyl group, a tertiary butyl group, or a trifluoromethyl group, or still more preferably a fluorine atom, a hydrogen atom, or a trifluoromethyl group, —O—, —CO—, —CO—O—, or —O—CO—.

The unit is still more preferably —CR₄R₅— wherein R₄ and R₅ each preferably represent a hydrogen atom, a halogen atom, or a linear or branched alkyl group having 1 to 10 carbon atoms in which a hydrogen atom of the alkyl group may be substituted with a fluorine atom, more preferably a hydrogen atom, a fluorine atom, a methyl group, a tertiary butyl group, or a trifluoromethyl group, or still more preferably a fluorine atom, a hydrogen atom, or a trifluoromethyl group, or —CO—.

Ring B is a cyclic group which has a nitrogen atom bonded to M and may have a substituent. Examples of the cyclic group preferably include a pyridyl group, a pyrazinyl group, a pyrimidyl group, a pyridazinyl group, a triazinyl group, a quinolinyl group, an isoquinolinyl group, a phenanthridinyl group, an acridinyl group, a naphthyridinyl group, a quinoxalinyl group, a quinazolinyl group, a cinnolinyl group, a phthalazinyl group, a phenanthrolyl group, a thiazolyl group, an isothiazolyl group, an imidazolyl group, a pyrazolyl group, an oxazolyl group, an isoxazolyl group, a benzothiazolyl group, a benzoisothiazolyl group, a benzoimidazolyl group, a benzopyrazolyl group, a benzoxazolyl group, a benzoisoxazolyl group, imidazolinyl group, a pyrazolinyl group, an oxazolinyl group.

More preferably, there are used a pyridyl group, a pyrazinyl group, a pyrimidyl group, a triazinyl group, a quinolinyl group, an isoquinolinyl group, a quinoxalinyl group, a phenanthrolyl group, a thiazolyl group, an isothiazolyl group, imidazolyl group, a pyrazolyl group, an oxazolyl group, and an isoxazolyl group.

Still more preferably, there are used a pyridyl group, a thiazolyl group, an isothiazolyl group, an imidazolyl group, a pyrazolyl group, an oxazolyl group, and an isoxazolyl group.

In addition, as the substituents of the cyclic group, a halogen atom, a linear or branched alkyl group, a linear or branched alkyl group which is substituted with fluorine atom(s), an alkoxyl group, a disubstituted amino group, an aryl group, and a heteroaryl group are preferable, a fluorine atom, a methyl group, an ethyl group, a trifluoromethyl group, a methoxy group, an ethoxy group, a diphenylamino group, and a dimethylamino group are more preferable, and a methyl group, an ethyl group, a methoxy group, and a dimethylamino group are still more preferable.

The central metal of the metal complex is not particularly limited but is preferably Ir, Pt, Rh, or Ru, or more preferably Ir or Pt.

The metal complex of the present invention has a ligand having, in a partial structure thereof, a non-aromatic cyclic group containing an alkylene group containing a fluorine atom. The introduction of a fluorine atom into a molecule of the metal complex is expected to suppress an intermolecular action. As a result, the phenomenon in which the emission efficiency lowers with increase of a guest material in a host material (referred to as “concentration quenching”), the phenomenon being often observed in a light-emitting layer of an organic electroluminescent device, and the phenomenon becoming a problem in the case of formation of a host-guest type light-emitting layer, can be suppressed. Accordingly, the dispersion concentration of a light-emitting material in a host material can be increased, whereby a light-emitting device having a high concentration of the light-emitting material and high emission efficiency can be realized.

Further, a light-emitting device having a light-emitting layer which is not formed of a mixture of a guest and a host but is formed only of the compound of the present invention as a guest material (in other words, the content of the compound in the light-emitting layer is 100%) can also be realized.

In addition, weakening the intermolecular action lowers the sublimation temperature, which prevents the decomposition of the compound upon vacuum deposition, and enables stable formation of a film from the compound by vapor deposition. Further, the weakening facilitates the application of sublimation purification to the purification of the compound. The number of fluorine atoms is preferably one or more, more preferably two or more, and still more preferably four or more. Alternatively, it is preferred that the ring structure A of the general formula (1) is constituted only of fluorine atom(s) and carbon atoms.

In addition, by introducing fluorine atom(s) into position(s) adjacent to the olefin skeleton of the ring structure A of the general formula (1), β hydrogen(s) of the metal-carbon bond and y hydrogen(s) present via the olefin can be replaced by fluorine atom(s). It is generally known that substituting hydrogen at β-position of a metal-carbon bond with a fluorine atom suppresses the reductive elimination of the metal-carbon bond. Therefore, a ligand of the metal complex of the present invention is preferably such that hydrogen(s) at β-position of the metal-carbon bond is replaced by fluorine atom(s), and is more preferably such that all hydrogen atoms adjacent to the olefin are each substituted with a fluorine atom. As a result, the structure of the complex is expected to be stabilized, and a device using the complex can be expected to be less susceptible to degradation and to be improved in durability performance.

Of such metal complex compounds, those metal complex compounds having a skeleton with a partial structure represented by the following general formula (7), (8), (9), (10), or (11) are preferable.

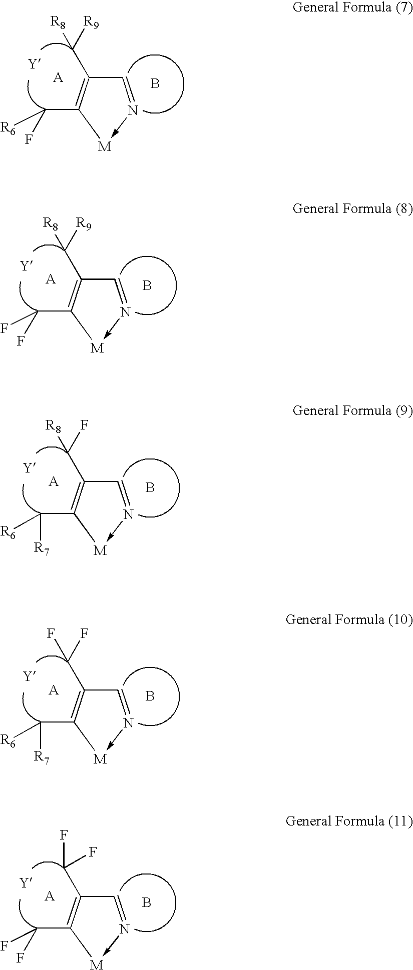

The central metal of the metal complex is not particularly limited but is preferably Ir, Pt, Rh, or Ru, more preferably Ir or Pt, or still more preferably Ir.

The ring structure A is a non-aromatic cyclic group which has a carbon atom bonded to M, includes at least one olefin structure and may have a substituent.

Y′ preferably represents an alkylene group having 0 to 4 carbon atoms, and more preferably represents an alkylene group having 1 or 2 carbon atoms. In the alkylene group, one methylene group or two non-adjacent methylene groups may each be replaced by —O—, —CO—O—, —O—CO—, —S—, —CR₁═CR₂—, —NR₃— where R₁, R₂ and R₃ may each be substituted with a hydrogen atom or a linear or branched alkyl group having 1 to 10 carbon atoms in which a hydrogen atom of the alkyl group may be substituted with a fluorine atom, or —CO—. In the alkylene group, a hydrogen atom may be substituted with a linear or branched alkyl group having 1 to 10 carbon atoms in which a hydrogen atom of the alkyl group may be substituted with a fluorine atom, or with a fluorine atom.

A unit which constitutes the alkylene group is preferably —CR₄R₅— where R₄ and R₅ each preferably represent a hydrogen atom, a halogen atom, or a linear or branched alkyl group having 1 to 10 carbon atoms in which a hydrogen atom of the alkyl group may be substituted with a fluorine atom, more preferably a hydrogen atom, a fluorine atom, a methyl group, a tertiary butyl group, or a trifluoromethyl group, or still more preferably a fluorine atom, a hydrogen atom, or a trifluoromethyl group, —O—, —CO—O—, —O—CO—, —NR₃— where R₃ preferably represents a hydrogen atom, or a linear or branched alkyl group having 1 to 10 carbon atoms in which a hydrogen atom of the alkyl group may be substituted with a fluorine atom, more preferably a methyl group, a tertiary butyl group, or a trifluoromethyl group, or still more preferably a methyl group or a trifluoromethyl group, —CO—O—, —O—CO—, or —CO—.

The unit is more preferably —CR₄R₅— where R₄ and R₅ each preferably represent a hydrogen atom, a halogen atom, or a linear or branched alkyl group having 1 to 10 carbon atoms in which a hydrogen atom of the alkyl group may be substituted with a fluorine atom, more preferably a hydrogen atom, a fluorine atom, a methyl group, a tertiary butyl group, or a trifluoromethyl group, or still more preferably a fluorine atom, a hydrogen atom, or a trifluoromethyl group, —O—, —CO—, —CO—O—, or —O—CO—.

The unit is still more preferably —CR₄R₅— where R₄ and R₅ each preferably represent a hydrogen atom, a halogen atom, or a linear or branched alkyl group having 1 to 10 carbon atoms in which a hydrogen atom of the alkyl group may be substituted with a fluorine atom, more preferably a hydrogen atom, a fluorine atom, a methyl group, a tertiary butyl group, or a trifluoromethyl group, or still more preferably a fluorine atom, a hydrogen atom, or a trifluoromethyl group, or —CO—.

Ring structure B is a cyclic group having a portion that coordinates with a metal atom via a nitrogen atom and which may have a substituent as described below. Examples of the cyclic group preferably include a pyridyl group, a pyrazinyl group, a pyrimidyl group, a pyridazinyl group, a triazinyl group, a quinolinyl group, an isoquinolinyl group, a phenanthridinyl group, an acridinyl group, a naphthyridinyl group, a quinoxalinyl group, a quinazolinyl group, a cinnolinyl group, a phthalazinyl group, a phenanthrolyl group, a thiazolyl group, an isothiazolyl group, an imidazolyl group, a pyrazolyl group, an oxazolyl group, an isoxazolyl group, a benzothiazolyl group, a benzoisothiazolyl group, a benzoimidazolyl group, a benzopyrazolyl group, a benzoxazolyl group, and a benzoisoxazolyl group.

More preferably, there are used a pyridyl group, a pyrazinyl group, a pyrimidyl group, a triazinyl group, a quinolinyl group, an isoquinolinyl group, a quinoxalinyl group, a phenanthrolyl group, a thiazolyl group, an isothiazolyl group, an imidazolyl group, a pyrazolyl group, an oxazolyl group, and an isoxazolyl group.

Still more preferably, there are used a pyridyl group, a thiazolyl group, an isothiazolyl group, an imidazolyl group, a pyrazolyl group, an oxazolyl group, and an isoxazolyl group.

In addition, as the substituents of the cyclic groups, a halogen atom, a linear or branched alkyl group, a linear or branched alkyl group which is substituted by a fluorine atom, an alkoxyl group, a diphenylamino group, a dialkylamino group, an aryl group, and a heteroaryl group are preferable; a fluorine atom, a methyl group, an ethyl group, a trifluromethyl group, a methoxy group, an ethoxy group, and a dimethylamino group are more preferable; and a methyl group, an ethyl group, a methoxy group, and a dimethylamino group are still more preferable.

R₆, R₇, R₈, and R₉ each preferably represent a hydrogen atom, a halogen atom, or a linear or branched alkyl group having 1 to 10 carbon atoms in which a hydrogen atom of the alkyl group may be substituted with a fluorine atom; more preferably a hydrogen atom, a fluorine atom, a methyl group, a tertiary butyl group, or a trifluoromethyl group; and still more preferably a fluorine atom, a hydrogen atom, a trifluoromethyl group, or a methyl group.

Next, the general formula (2) representing a more specific structure will be described.

MLₘL′ₙ (2)

In the above formula, L and L′ represent bidentate ligands different from each other, m represents 1, 2, or 3, n represents 0, 1, or 2 with the proviso that m+n represents 2 or 3, a partial structure MLₘ is represented by the following general formula (3), and a partial structure ML′ₙ is represented by the following general formula (4), (5), or (6).

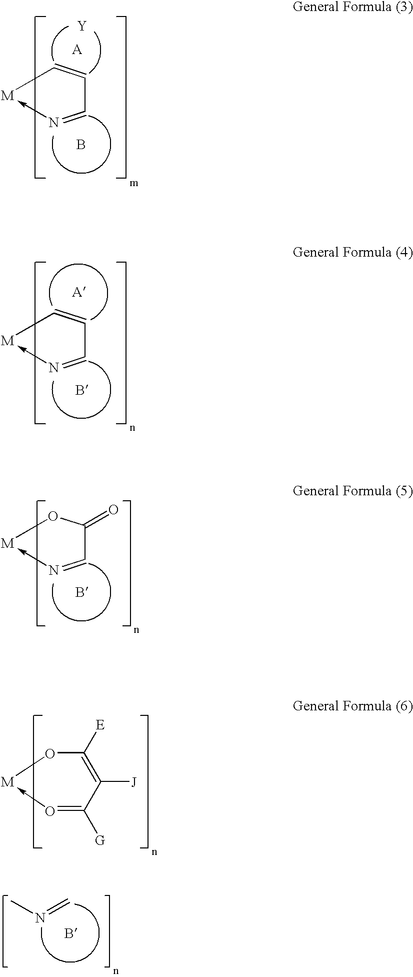

A, B, and Y are as defined for the general formula (1).

N represents a nitrogen atom, A′ represents a cyclic group which is bonded to a metal atom M via a carbon atom and may have a substituent, and B′ represents a cyclic group which is bonded to the metal atom M via a nitrogen atom and may have a substituent, provided that A′ and B′ are covalently bonded to each other.

The cyclic group A′ preferably represents any one of a phenyl group, a naphthyl group, a fluorenyl group, a thienyl group, a benzothienyl group, and a benzofuranyl group, and more preferably represents a phenyl group and a fluorenyl group.

Preferable examples of the substituent for the cyclic groups include a halogen atom, a linear or branched alkyl group, a linear or branched alkyl group which is substituted by a fluorine atom, an alkoxyl group, a disubstituted amino group, and a cyano group. More preferable examples of the substituent for the cyclic groups include a fluorine atom, a methyl group, a trifluoromethyl group, a methoxy group, and a cyano group, and further more preferable examples thereof include a fluorine atom, a methyl group, and a methoxy group.

Preferable examples of the cyclic group B′ include a pyridyl group, a pyrazinyl group, a pyrimidyl group, a pyridazinyl group, a triazinyl group, a quinolinyl group, an isoquinolinyl group, a phenanthridinyl group, an acridinyl group, a naphthyridinyl group, a quinoxalinyl group, a quinazolinyl group, a cinnolinyl group, a phthalazinyl group, a phenanthrolyl group, a thiazolyl group, an isothiazolyl group, an imidazolyl group, a pyrazolyl group, an oxazolyl group, an isoxazolyl group, a benzothiazolyl group, a benzisothiazolyl group, a benziomidazolyl group, a benzopyrazolyl group, benzoxazolyl group, and a benzoisoxazolyl group.

More preferable examples thereof include a pyridyl group, a pyrazinyl group, a pyrimidyl group, a triazinyl group, a quinolinyl group, an isoquinolinyl group, a quinoxalinyl group, a phenanthrolyl group, a thiazolyl group, an isothiazolyl group, an imidazolyl group, a pyrazolyl group, an oxazolyl group, and an isoxazolyl group.

Further more preferable examples thereof include a pyridyl group, an imidazolyl group, a pyrazolyl group, a quinolinyl group, and an isoquinolinyl group.

Preferable examples of the substituent for the cyclic group include a halogen atom, a linear or branched alkyl group, a linear or branched alkyl group which is substituted by a fluorine atom, an alkoxyl group, and a dialkylamino group. More preferable examples of the substituent for the cyclic group include a fluorine atom, a methyl group, an ethyl group, a trifluoromethyl group, a methoxy group, an ethoxy group, and a dimethylamino group.

E and G each represent any one of a linear or branched alkyl group having 1 to 20 carbon atoms wherein one methylene group or at least 2 non-adjacent methylene groups of the alkyl group may be substituted by any one of —O—, —S—, —CO—, —CO—O—, —O—CO—, —CH═CH—, and —C≡C—, and a hydrogen atom of the alkyl group may be substituted by a fluorine atom; and an aromatic cyclic group which may have a substituent selected from a halogen atom, a cyano group, a nitro group, a trialkylsilyl group in which the alkyl groups each represent, independently of one another, a linear or branched alkyl group having 1 to 8 carbon atoms, and a linear or branched alkyl group having 1 to 20 carbon atoms in which one methylene group or at least 2 non-adjacent methylene groups of the alkyl group may be substituted by any one of —O—, —S—, —CO—, —CO—O—, —O—CO—, —CH═CH—, and —C≡C—, and a hydrogen atom of the alkyl group may be substituted by a fluorine atom.

E and G each preferably represent any one of a methyl group, a tertiary-butyl group, a trifluoromethyl group, a methoxy group, an ethoxy group, and a phenyl group, and more preferably represent any one of a methyl group, a tertiary-butyl group, and a methoxy group.

J represents any one of a hydrogen atom; a halogen atom; a linear or branched alkyl group having 1 to 20 carbon atoms wherein one methylene group or at least 2 non-adjacent methylene groups may be substituted by any one of —O—, —S—, —CO—, —CO—O—, —O—CO—, —CH═CH—, and —C≡C—, and a hydrogen atom of the alkyl group may be substituted by a fluorine atom; and an aromatic cyclic group which may have a substituent selected from a halogen atom, a cyano group, a nitro group, a trialkylsilyl group in which the alkyl groups each represent, independently of one another, a linear or branched alkyl group having 1 to 8 carbon atoms, and a linear or branched alkyl group having 1 to 20 carbon atoms in which one methylene group or at least 2 non-adjacent methylene groups of the alkyl group may be substituted by any one of —O—, —S—, —CO—, —CO—O—, —O—CO—, —CH═CH—, and —C≡C—, and a hydrogen atom of the alkyl group may be substituted by a fluorine atom.

J preferably represents any one of a hydrogen atom, a methyl group, a trifluoromethyl group, a methoxy group, an ethoxy group, and a phenyl group, and more preferably represents one of a hydrogen atom and a methyl group.

A light-emitting layer of an organic light-emitting device is typically produced by vacuum deposition of both a host material and a light-emitting material from a deposition source (co-deposition method). The emission efficiency of an organic light-emitting device having a light-emitting layer produced by the co-deposition method is largely affected by the concentration of a light-emitting material. Therefore, in order to stably produce a device having a high efficiency, the concentration of the light-emitting material needs to be accurately controlled. However, when producing a light-emitting layer by the co-deposition method, it is considered to be extremely difficult to uniform the doping concentration of the entirety of the light-emitting layer. Therefore, there is a need for the development of a phosphorescent material that realizes a light-emitting layer using no host material and formed only of a light-emitting material to provide a high emission efficiency.

When L′ is a non-light-emitting ligand, in the case where m+n=3 and n=2 in the general formula (2), the number of the light-emitting ligands contained in a molecule becomes ⅓ of that in the case where n=0. By this fact, it is expected that the lowering in luminance due to the concentration quenching described above can be suppressed, and the doping with the light-emitting material can be performed at a higher concentration. Further, the material can be expected to more suppress the concentration quenching because the material contains fluorine atoms as described above. The further suppression of the concentration quenching of the light-emitting material can be expected because of any one of those effects or synergy of those effects. Further, the suppression of the lowering in luminance due to concentration quenching can be expected even in a light-emitting layer using no host and formed only of a light-emitting material, and hence light emission with a higher luminance can be performed.

Specific exemplified compounds of the metal complex of the present invention are shown below. However, the compounds are merely representative examples, and the present invention is not limited thereto.

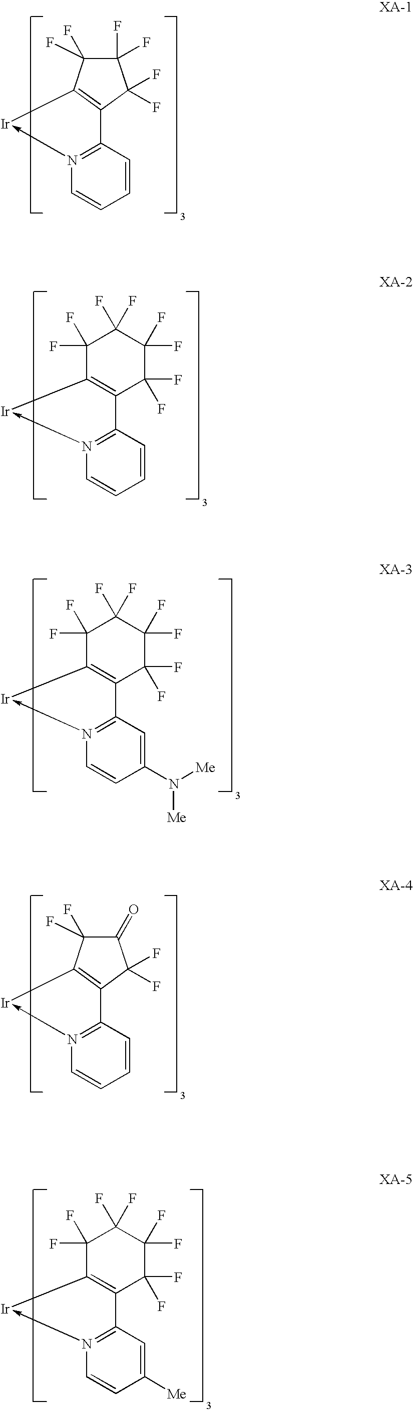

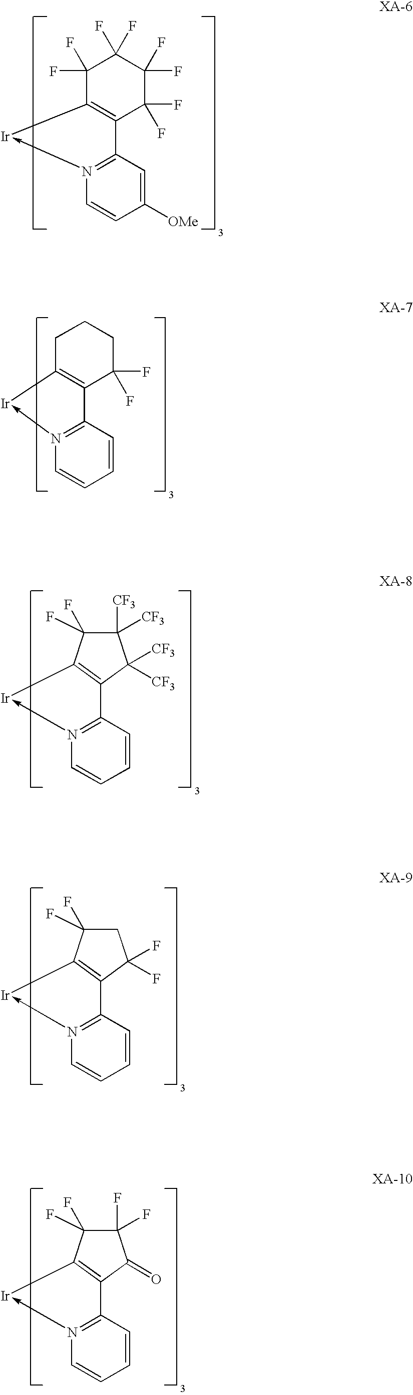

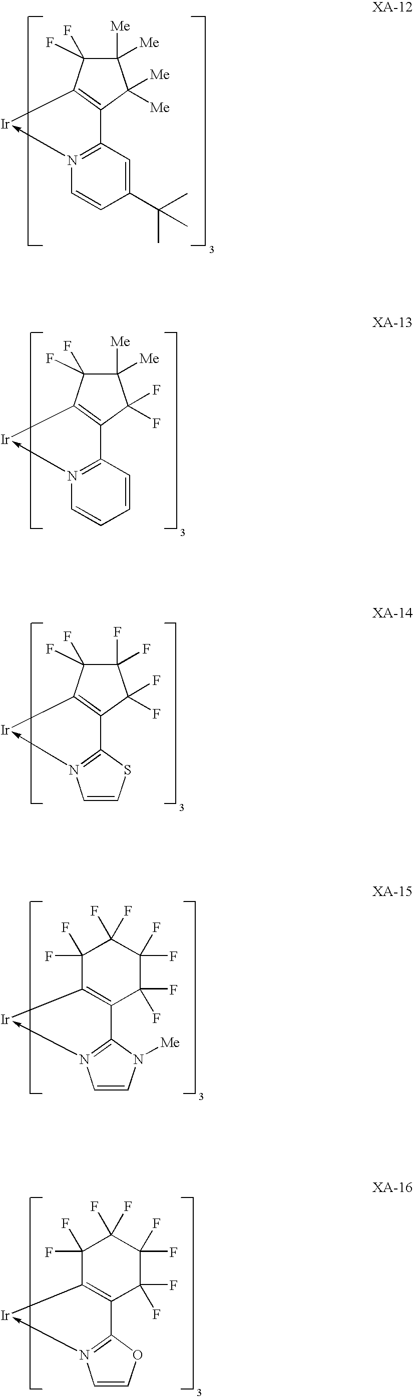

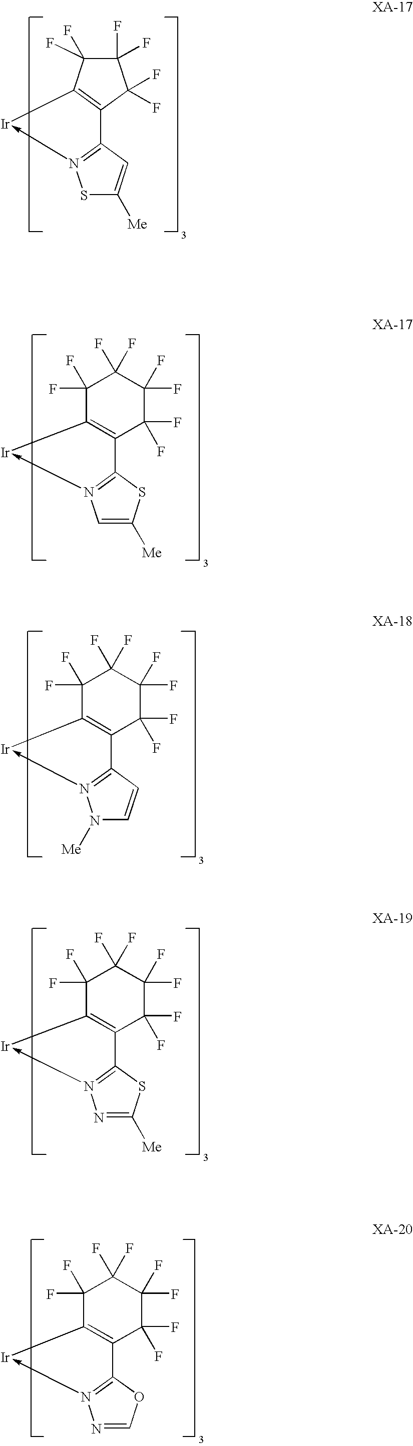

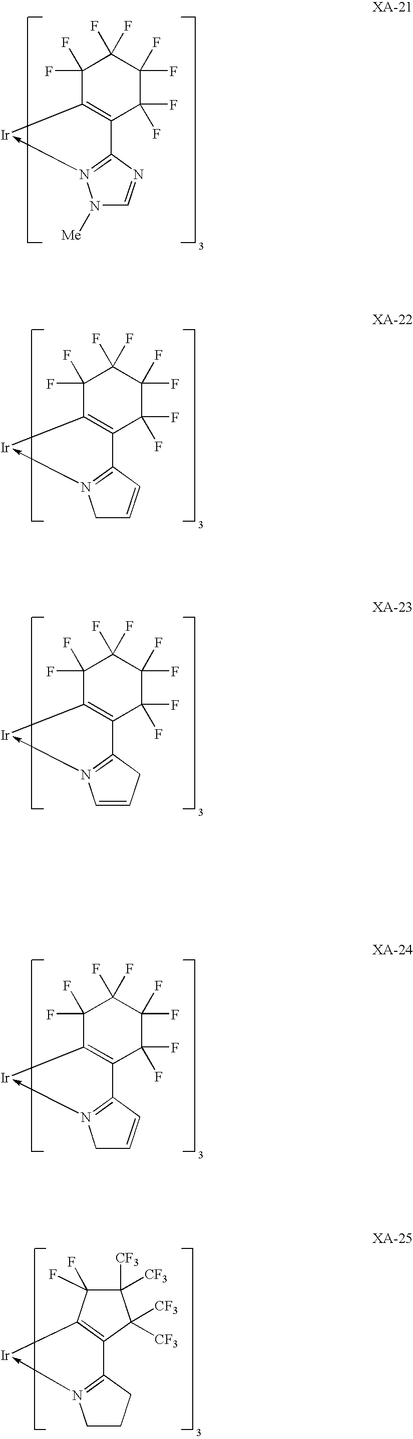

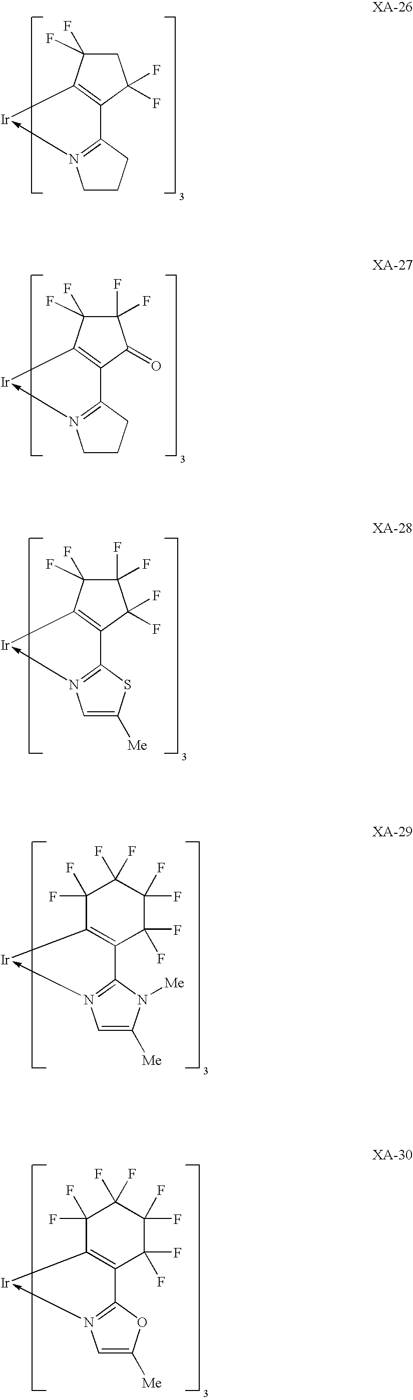

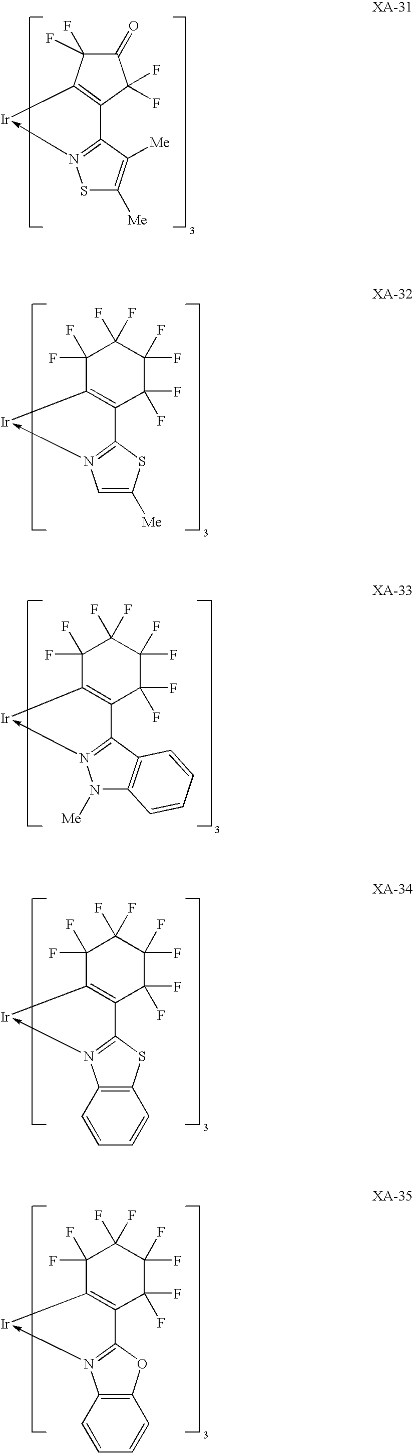

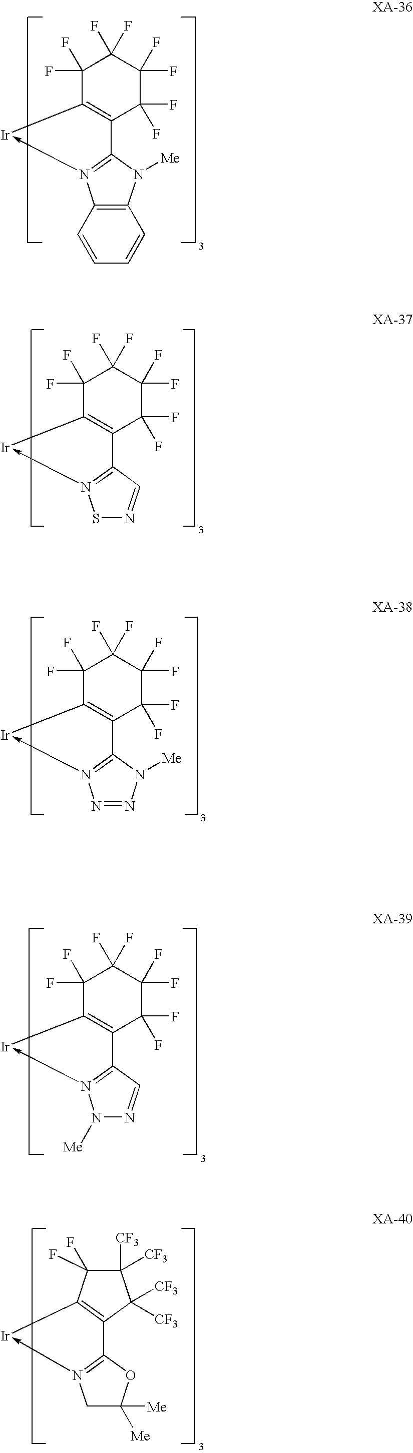

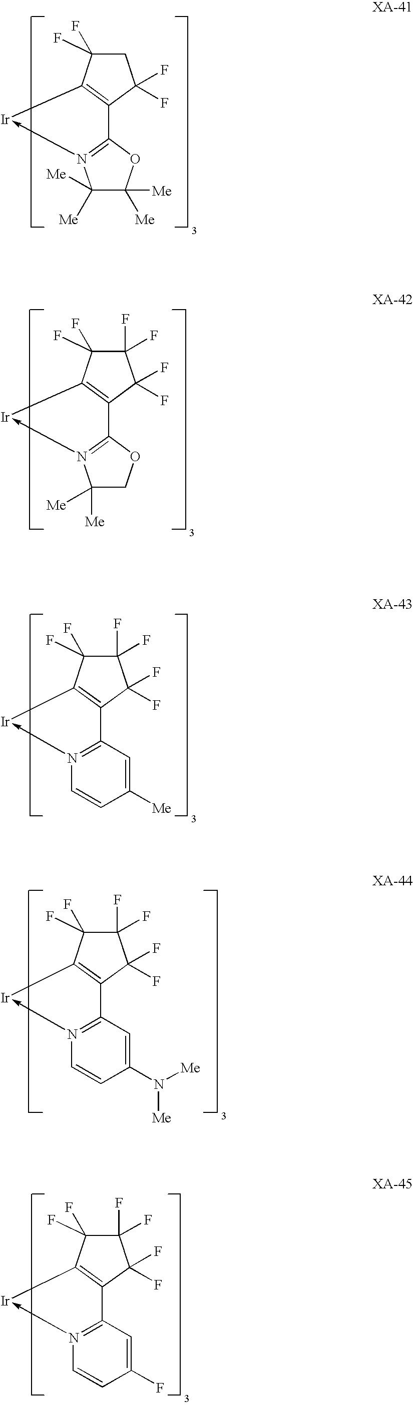

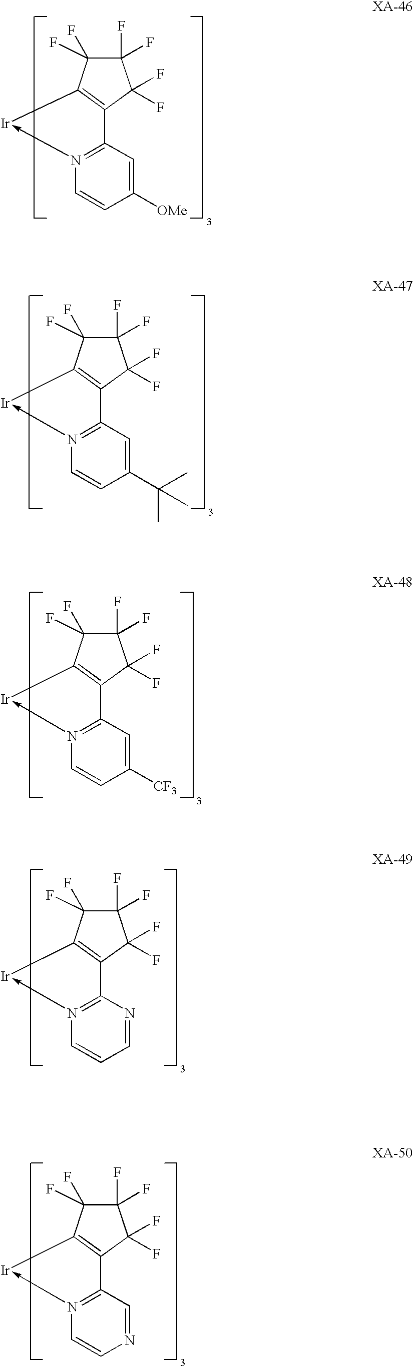

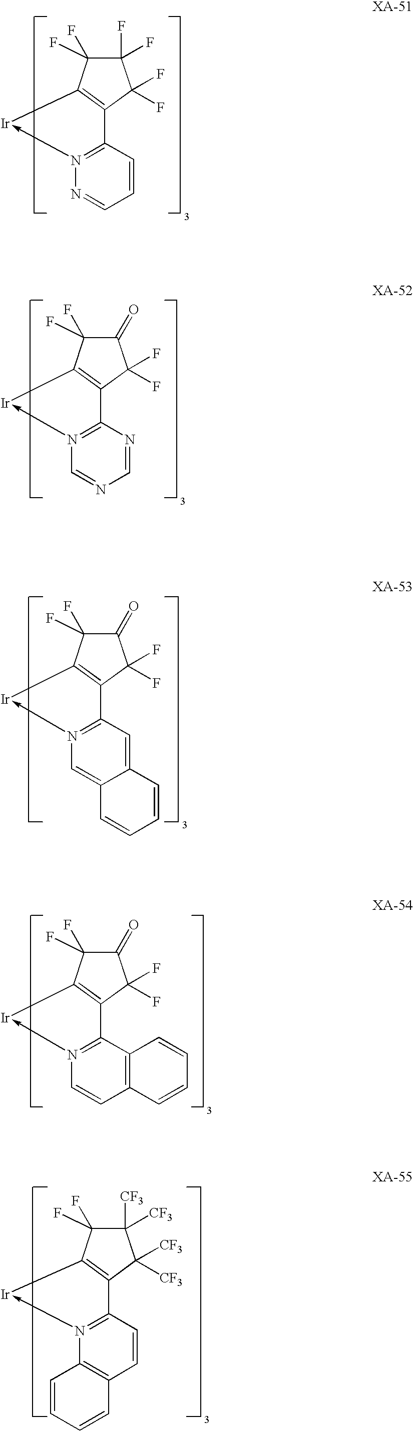

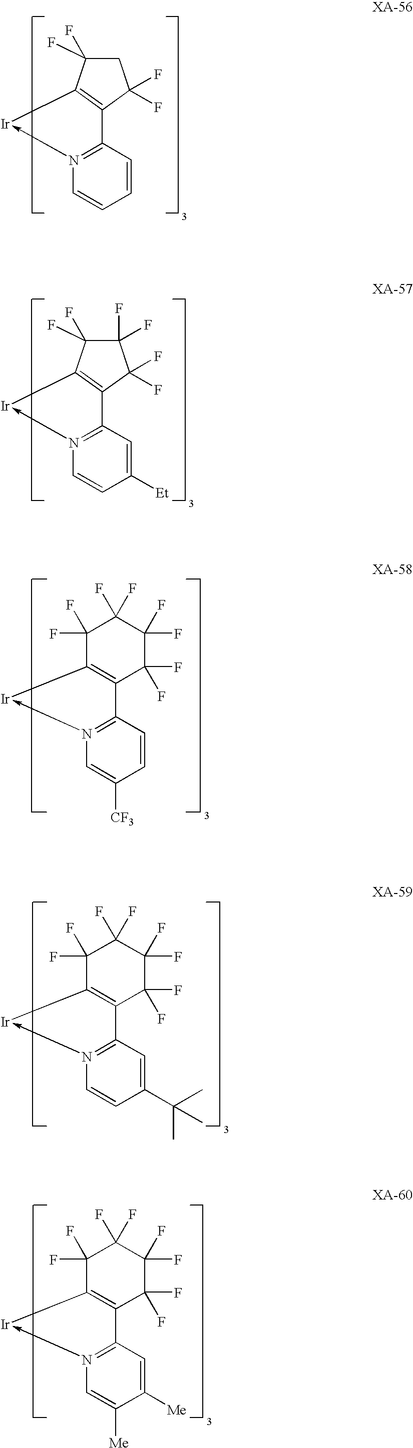

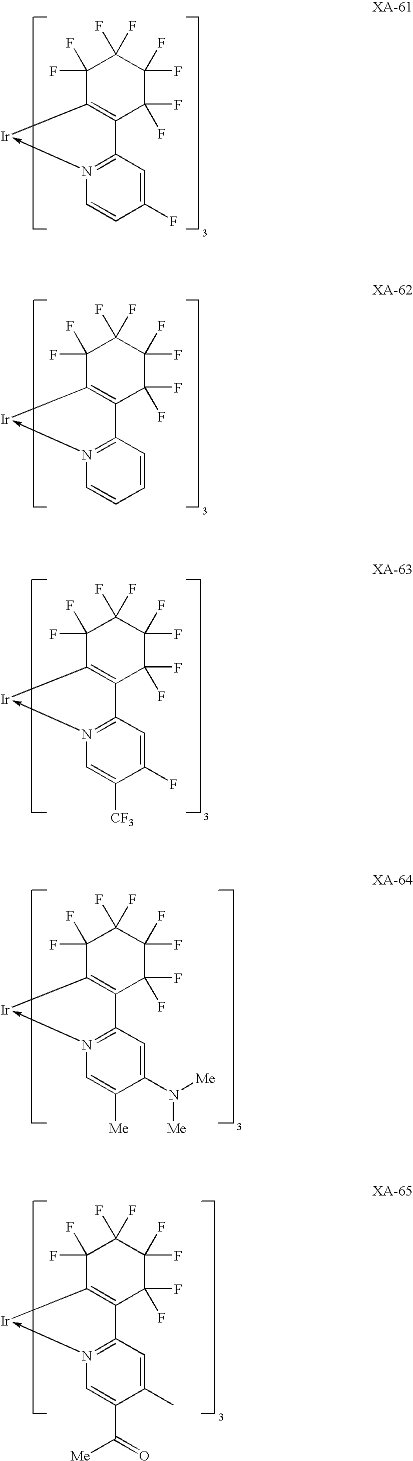

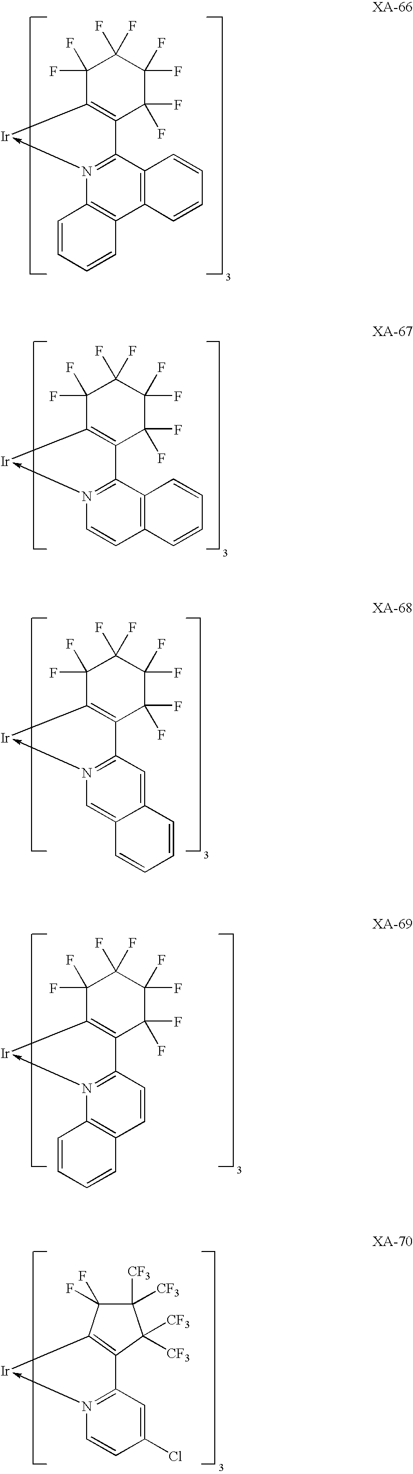

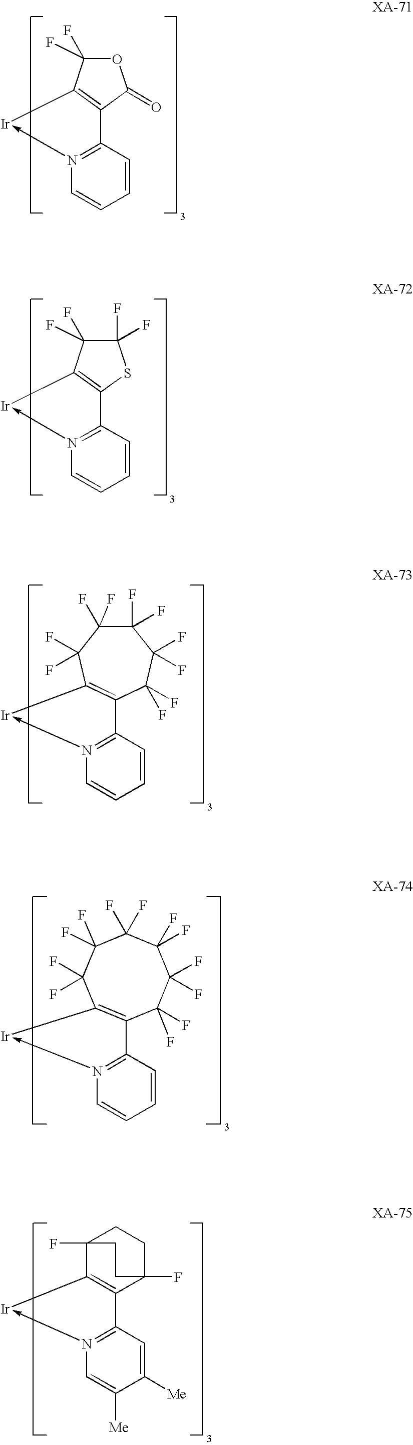

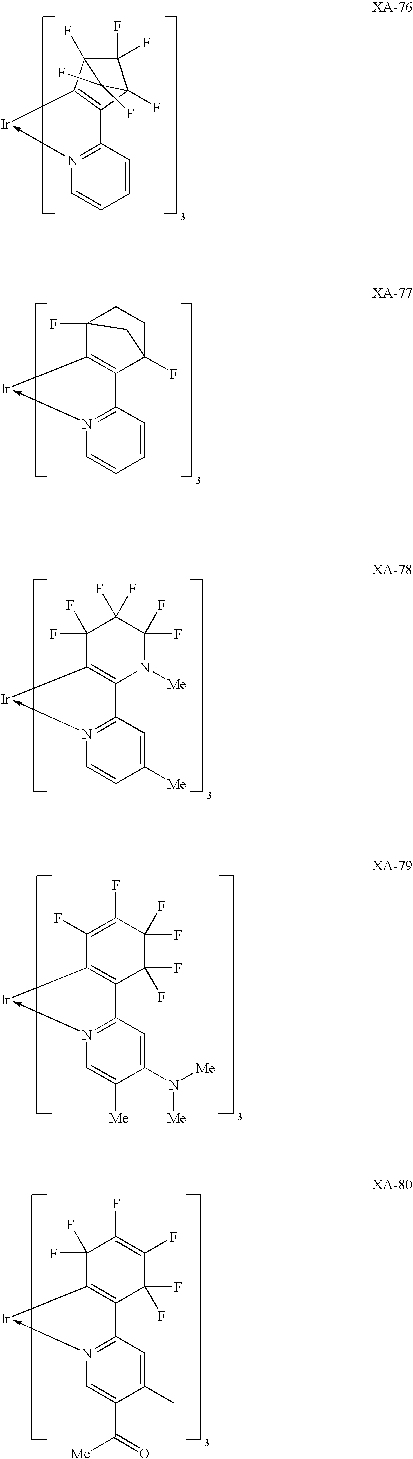

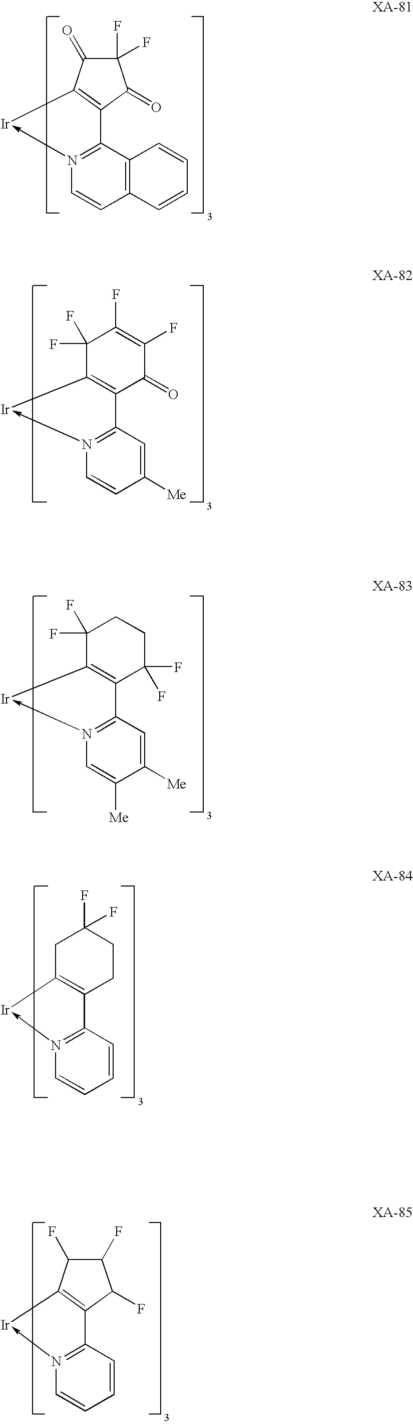

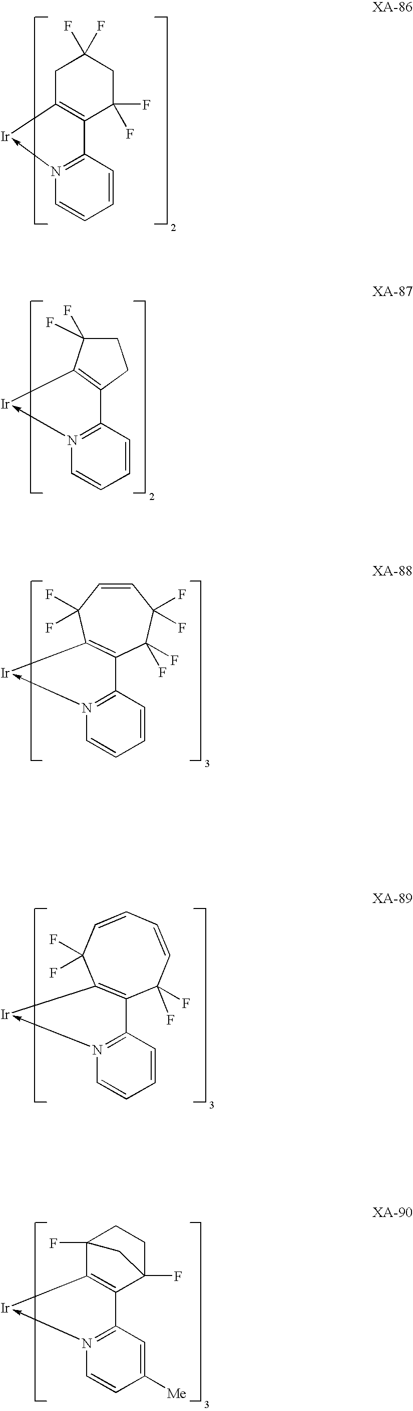

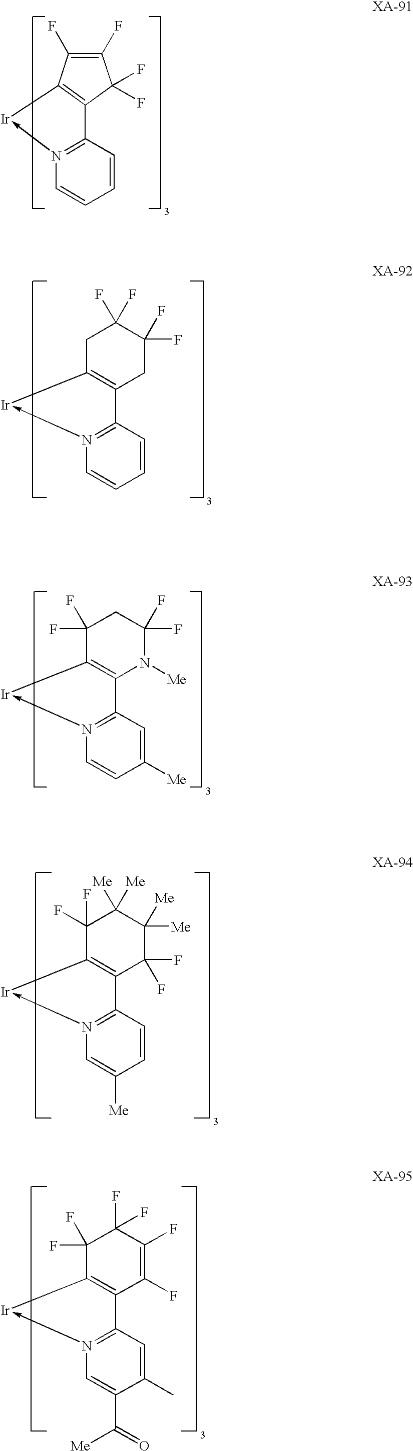

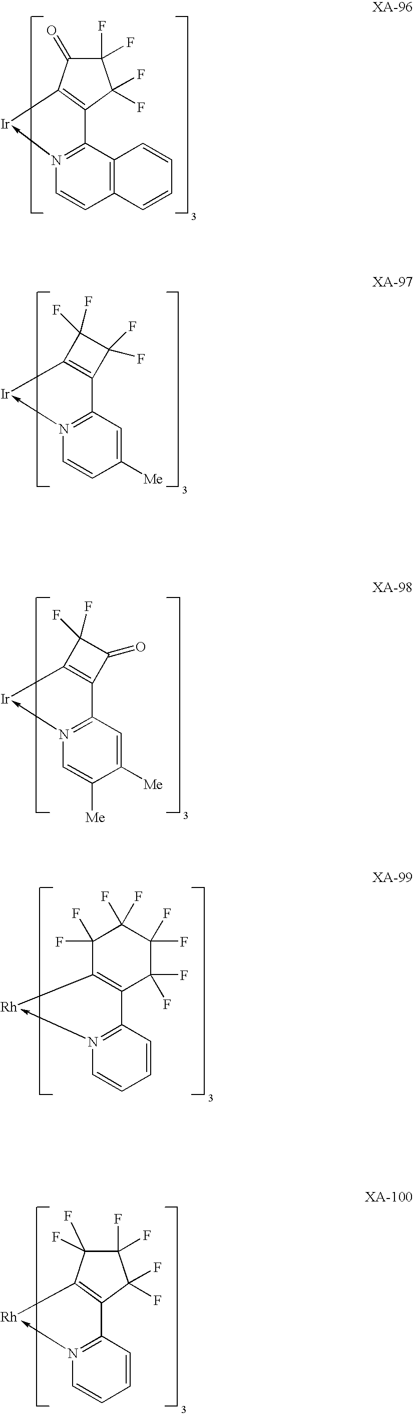

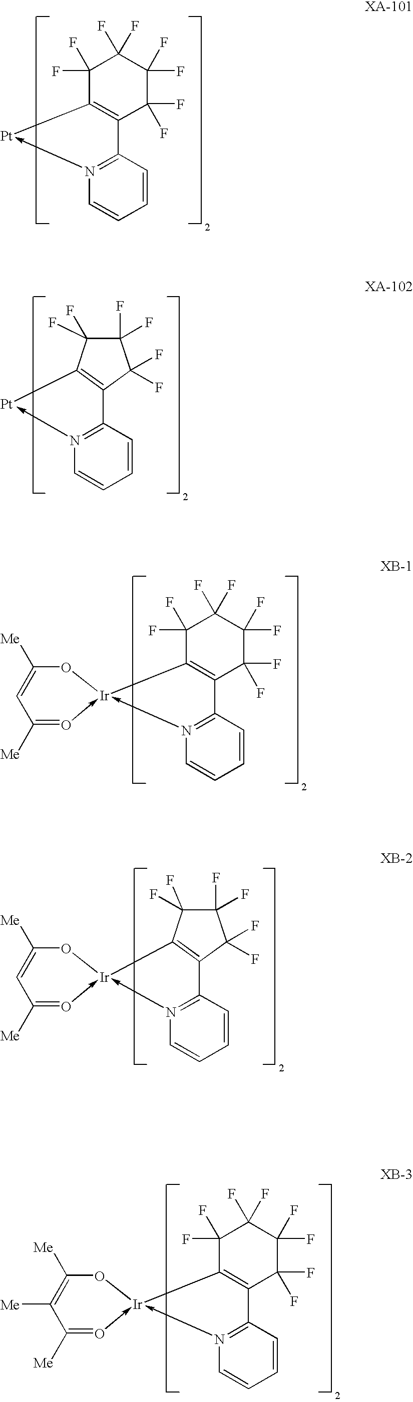

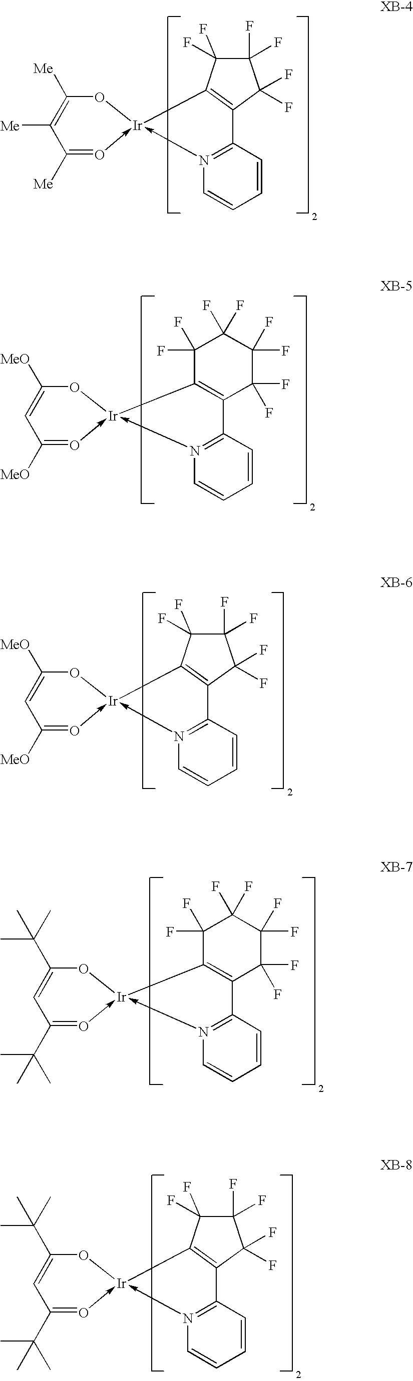

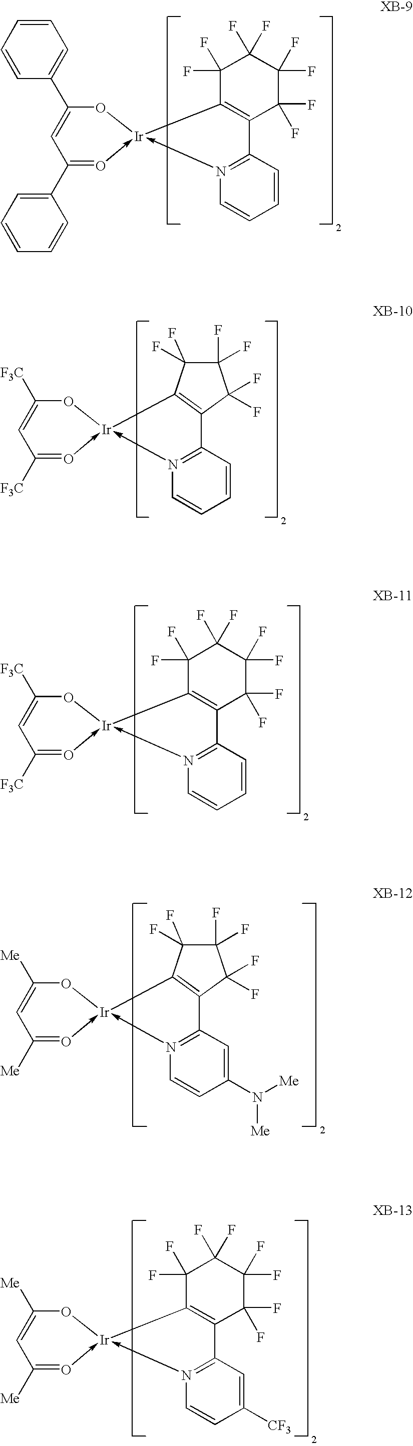

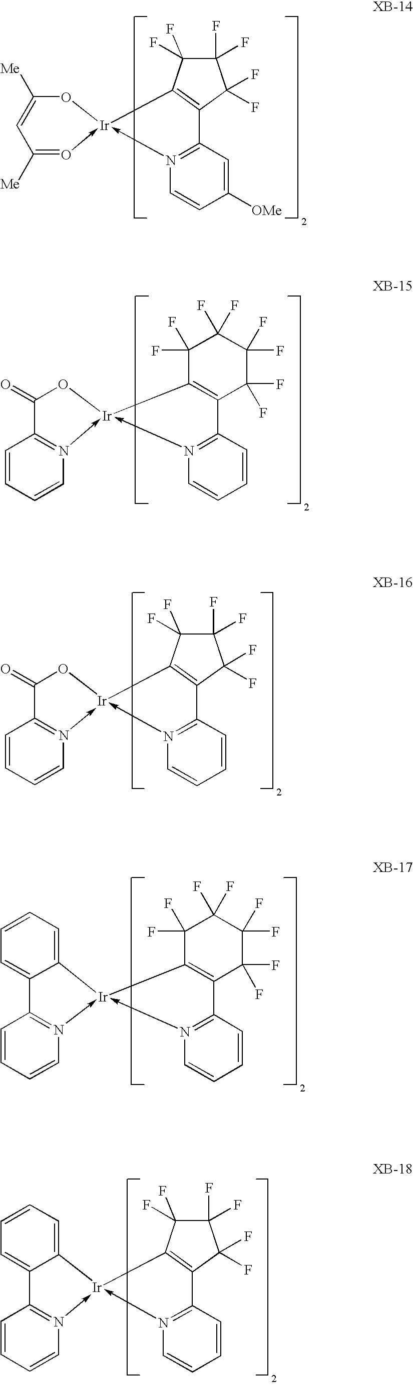

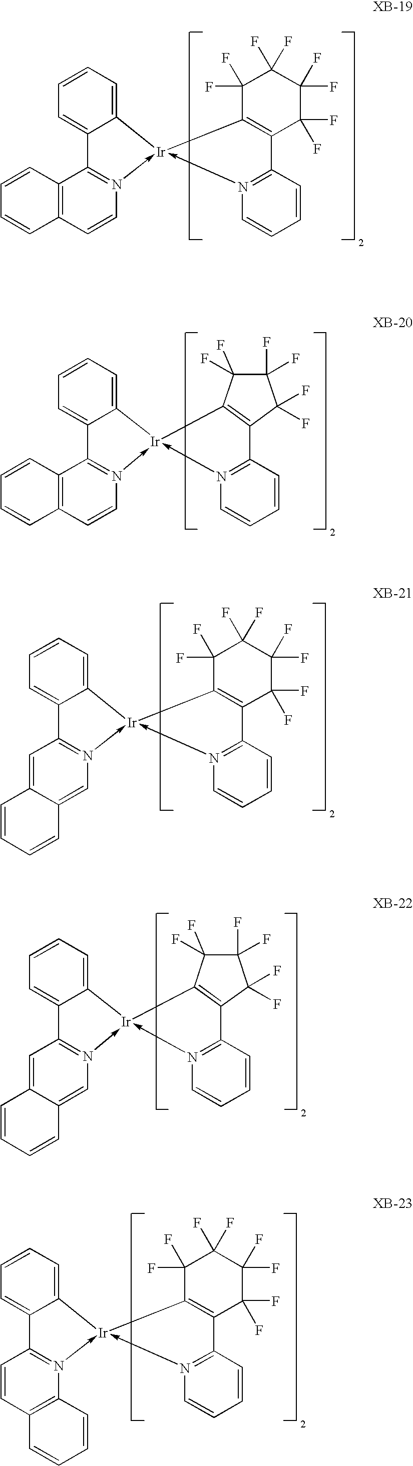

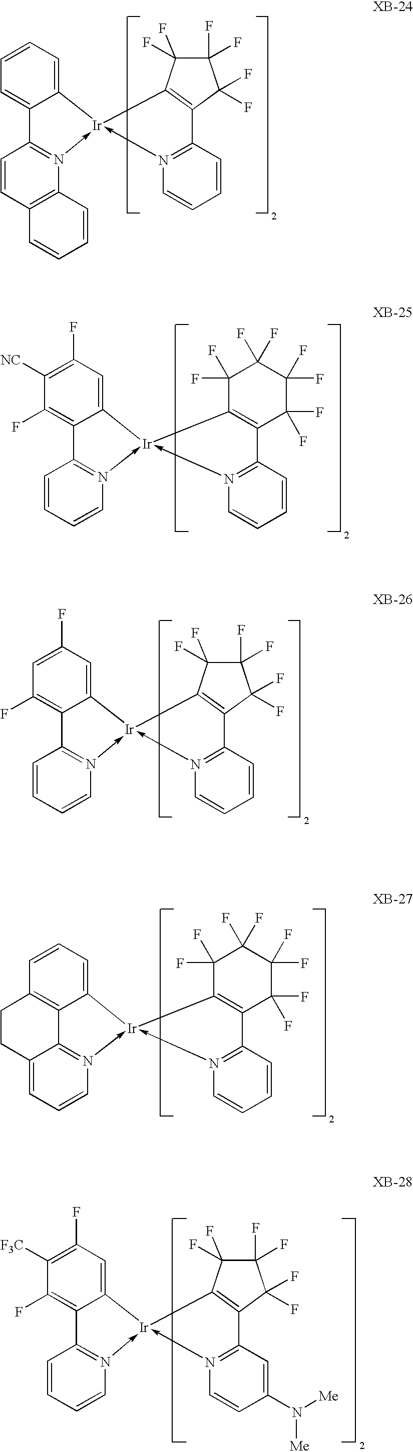

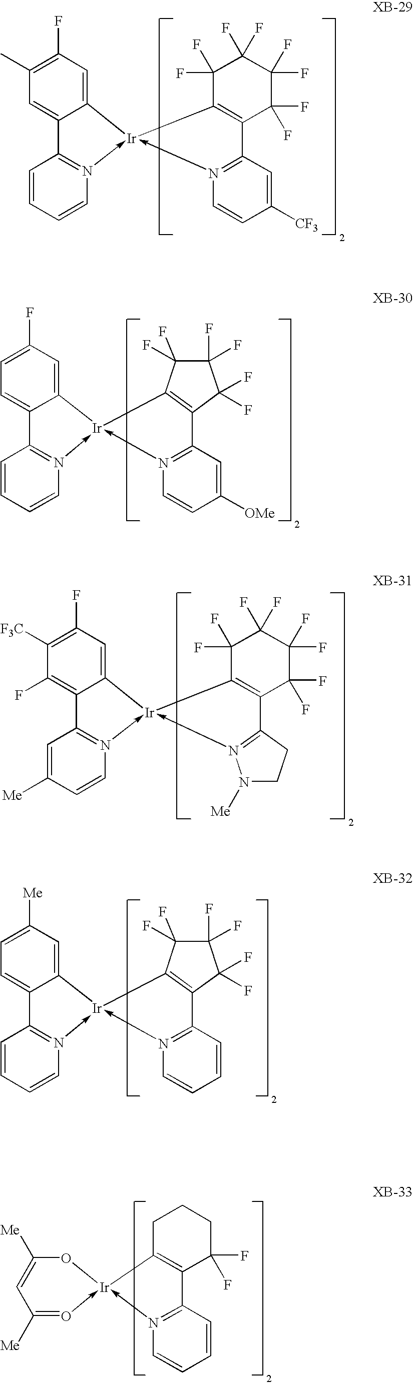

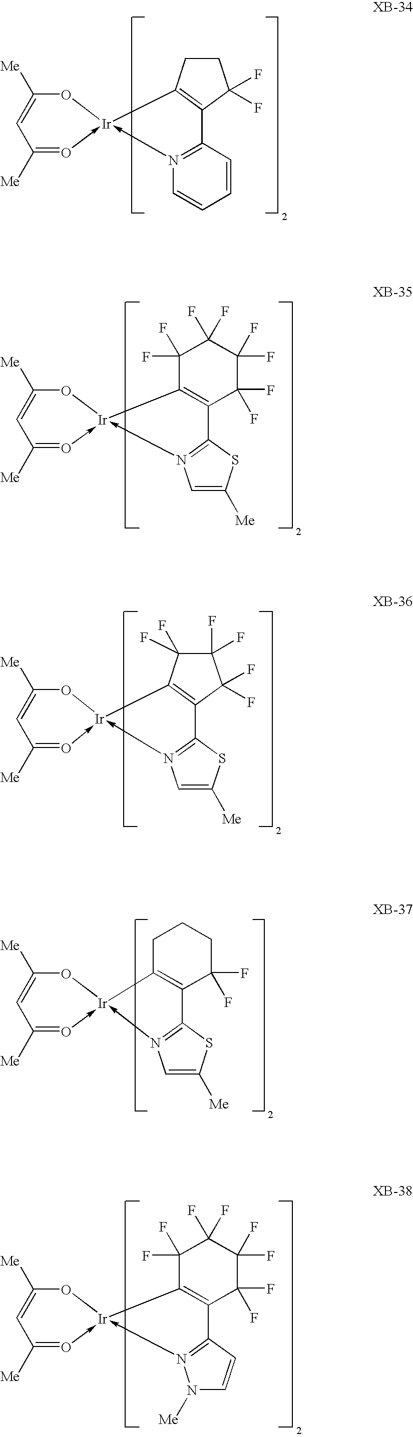

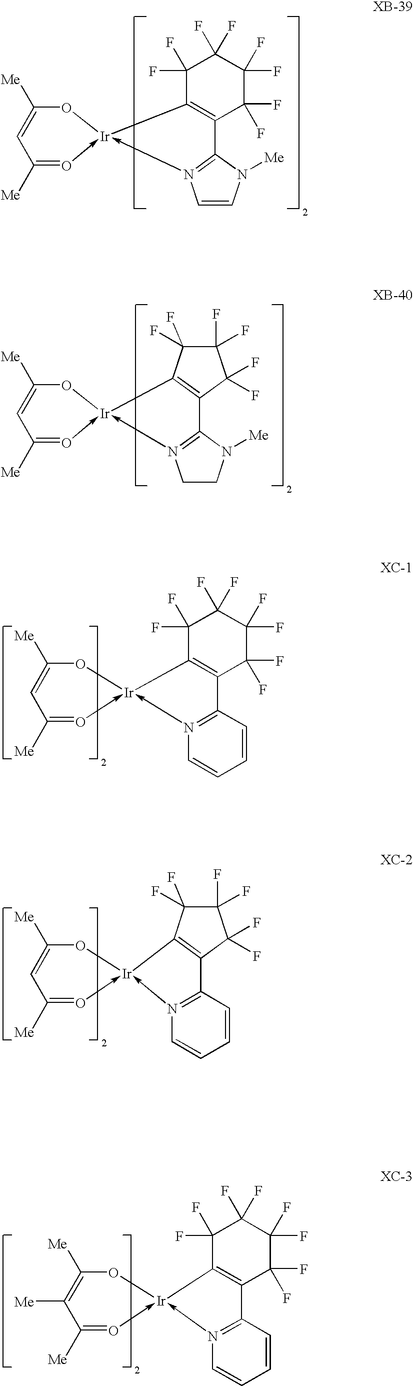

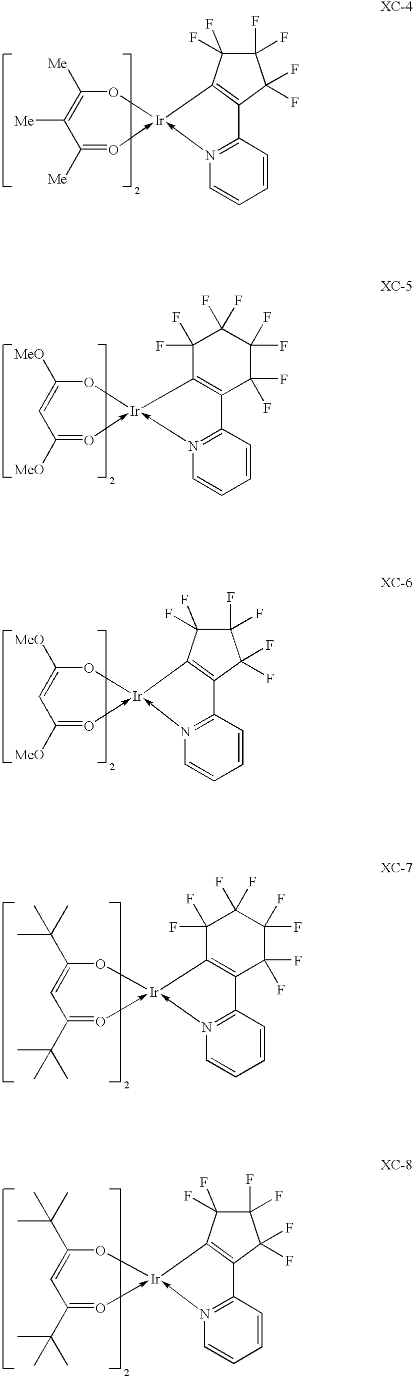

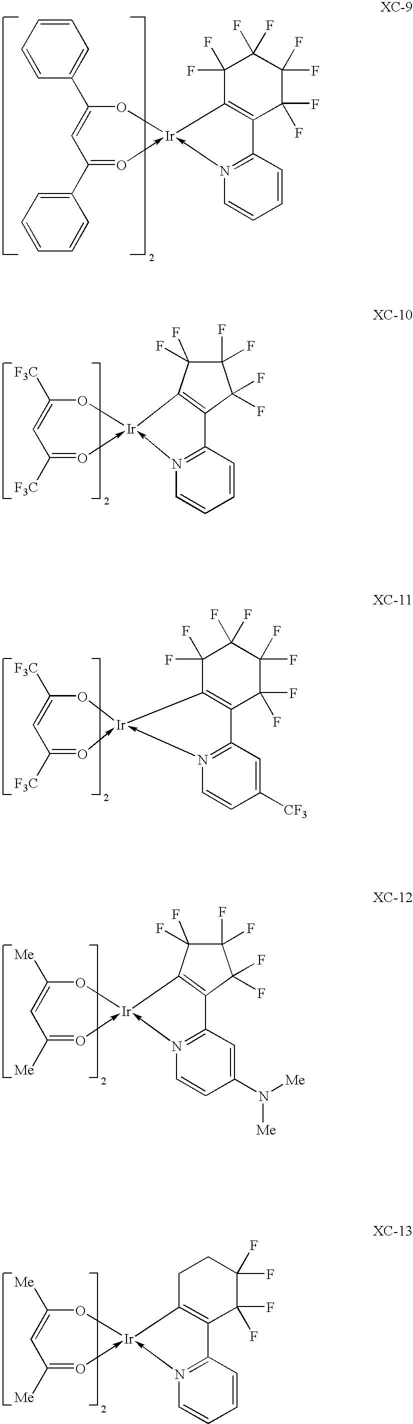

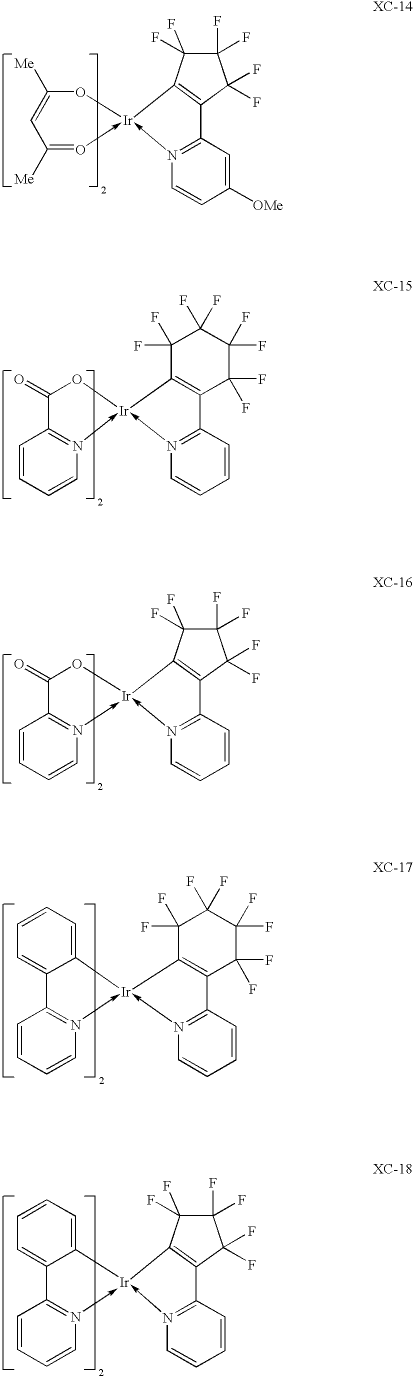

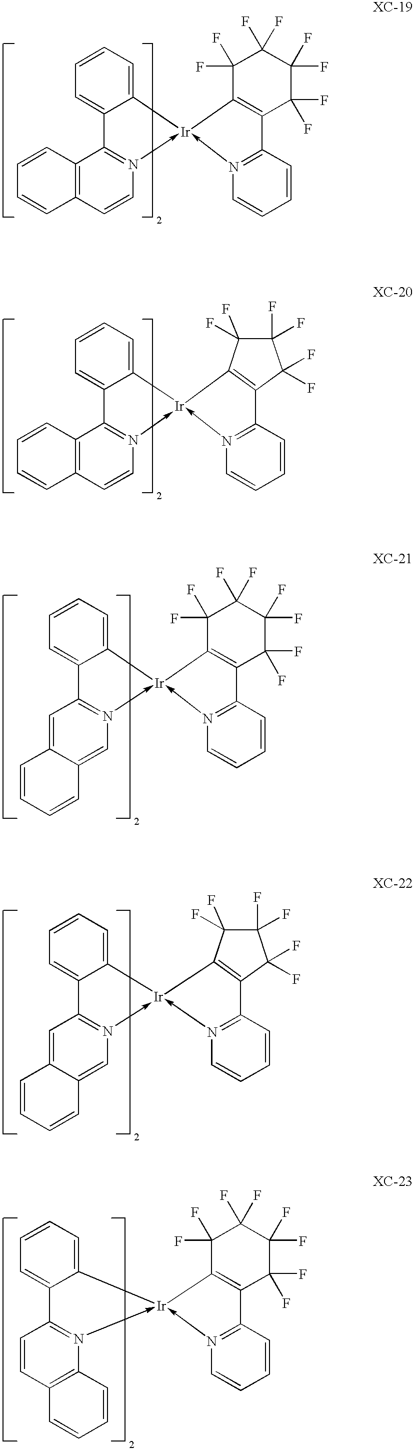

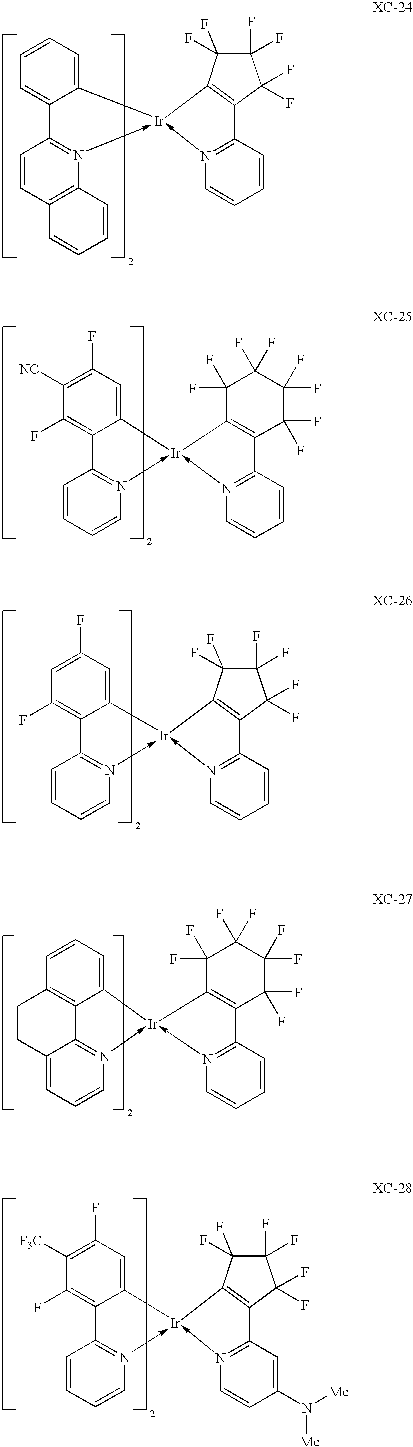

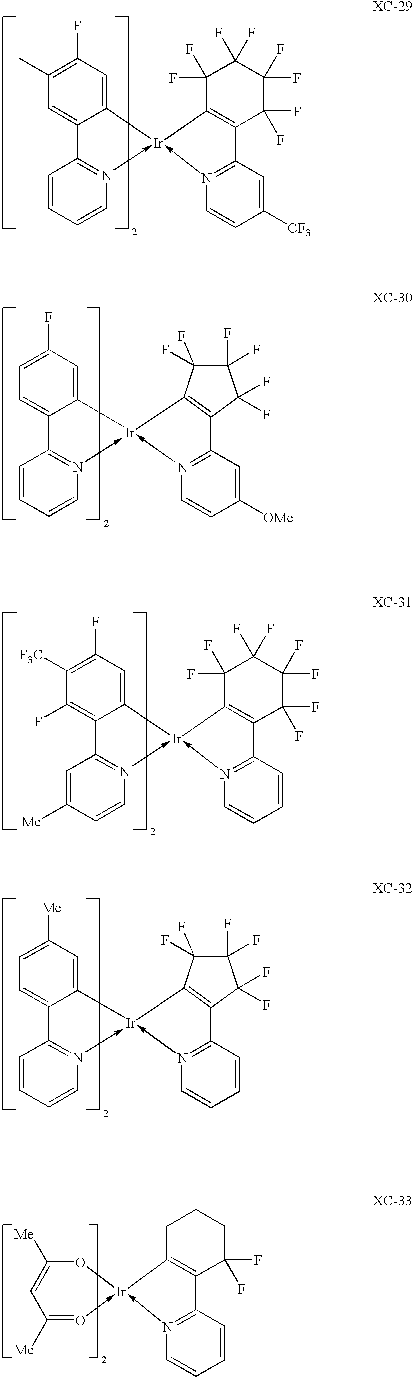

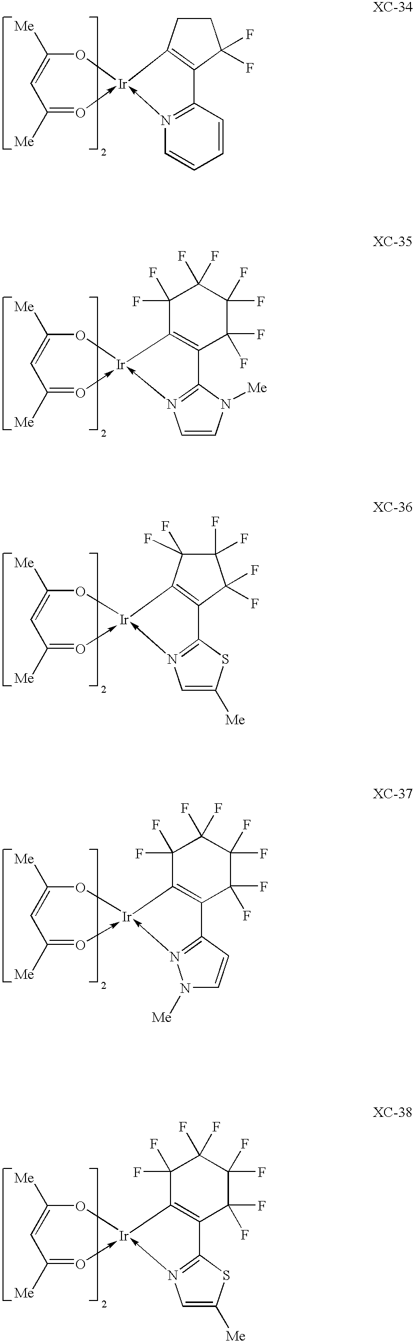

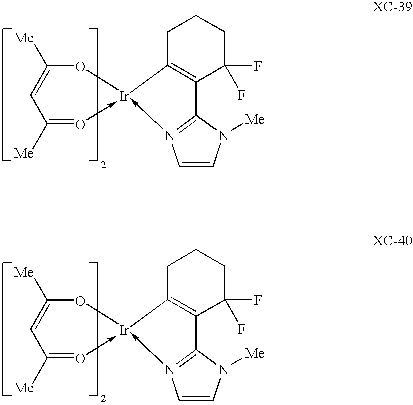

Next, a light-emitting device of the present invention is described.

An organic layer containing the metal complex of the present invention can be prepared by any one of film formation methods such as a vacuum deposition method, a casting method, a coating method, a spin coating method, and an inkjet method.

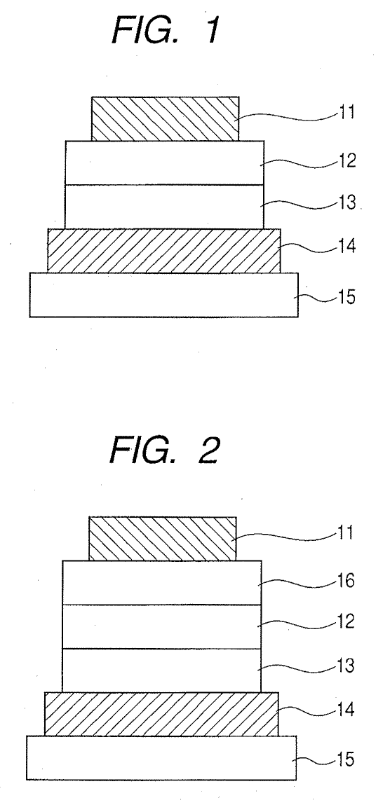

FIGS. 1 to 3 illustrate basic device structures of the light-emitting device of the present invention.

First, reference numerals shown in the figures are as follows: reference numeral 11 denotes a metal electrode; reference numeral 12 denotes a light-emitting layer; reference numeral 13 denotes a hole-transporting layer; reference numeral 14 denotes a transparent electrode; reference numeral 15 denotes a transparent substrate; reference numeral 16 denotes an electron-transporting layer; and reference numeral 17 denotes an exciton diffusion-prevention layer.

As illustrated in FIG. 1, an organic EL device generally includes a transparent substrate 15; a transparent electrode 14 having a thickness of 50 nm or more to 200 nm or less, which is arranged on the transparent substrate; a plurality of organic layers; and a metal electrode 11, and the plurality of organic film layers are interposed between the transparent electrode and the metal electrode.

FIG. 1 illustrates an example in which the organic layers include a light-emitting layer 12 and a hole-transporting layer 13. For the transparent electrode 14, for example, ITO having a large work function is used to facilitate the injection of holes from the transparent electrode 14 to the hole-transporting layer 13. For the metal electrode 11, a metal material having a small work function such as aluminum, magnesium, or an alloy thereof is used to facilitate the injection of electrons to the organic layers.

The compound of the present invention is used for the light-emitting layer 12, and for the hole-transporting layer 13 an electron donative material such as a triphenyldiamine derivative typified by α-NPD shown below can be appropriately used.

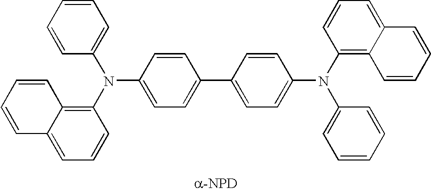

The device having the above-mentioned constitution shows electrical rectifying properties. When an electric field is applied in such a manner that the metal electrode 11 serves as a cathode and the transparent electrode 14 serves as an anode, electrons are injected from the metal electrode 11 to the light-emitting layer 12 and holes are injected from the transparent electrode 15 thereto.

The injected holes and electrons recombine in the light-emitting layer 12 to generate excitons, thereby emitting light. At this time, the hole-transporting layer 13 serves as an electron-blocking layer, whereby the recombination efficiency at an interface between the light-emitting layer 12 and the hole-transporting layer 13 increases to increase the emission efficiency.

In FIG. 2, an electron-transporting layer 16 is interposed between the metal electrode 11 and the light-emitting layer 12 illustrated in FIG. 1. In this case, by separating a light emitting function and electron-/hole-transporting functions to thereby provide a more effective carrier blocking structure, the emission efficiency is improved. For the electron-transporting layer 16, an oxadiazole derivative or the like can be used.

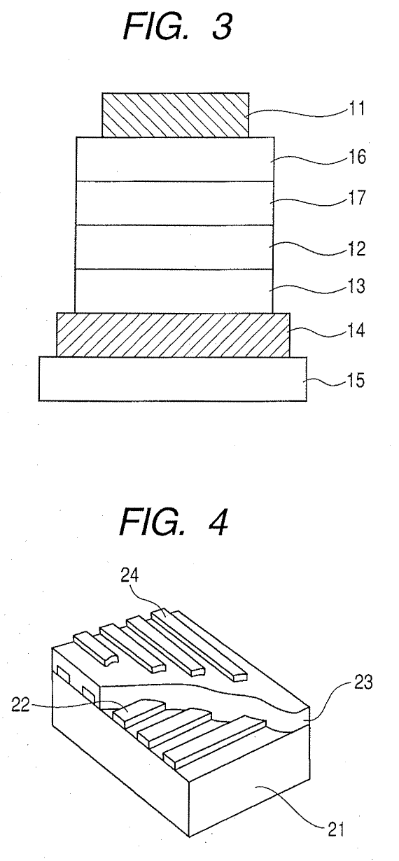

Further, as illustrated in FIG. 3, a four-layer structure is also preferably adopted which includes the hole-transporting layer 13, the light-emitting layer 12, an exciton diffusion-prevention layer 17, the electron-transporting layer 16, and the metal electrode 11 are stacked in the mentioned order on the transparent electrode 14 serving as an anode.

The light-emitting device having high efficiency according to the present invention can be applied to products which require energy saving or high luminance. Examples of such applications include: a light source of any one of a display apparatus, an illumination apparatus, and a printer; and a backlight for a liquid crystal display apparatus. The application of the light-emitting device of the present invention to a display apparatus can provide a lightweight and energy-saving flat panel display with a high level of visibility. In addition, for the light source of a printer, a laser light source of a laser beam printer which is widely used at present can be substituted by the light-emitting device of the present invention. An image can be formed by disposing devices which can be addressed independently from one another on an array and by performing a desired exposure with respect to a photosensitive drum by use thereof. The use of the light-emitting device of the present invention can significantly reduce the size of an apparatus. The light-emitting device of the present invention is expected to provide an energy-saving effect on the illumination apparatus or the backlight.

The device of the present invention can be used as the simple matrix type organic EL display such as illustrated in FIG. 4 and may be applied to a display of a system in which the light-emitting devices are driven using an active-matrix TFT drive circuit.

Hereinafter, an example of the device of the present invention in which an active-matrix substrate is used is described by referring to FIG. 6.

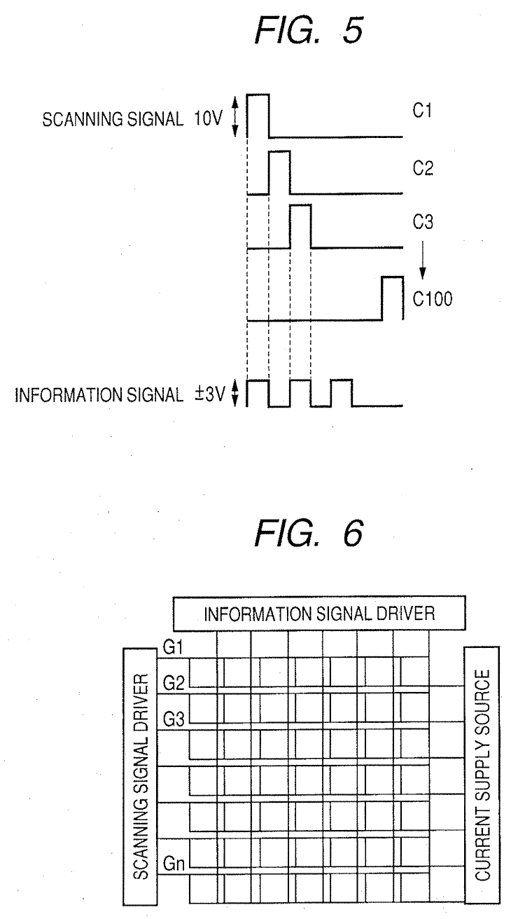

FIG. 6 is a schematic diagram illustrating an example of a constitution of a panel provided with EL devices and a driving unit. In the panel, there are disposed a scanning signal driver, an information signal driver, and a current supply source which are connected to gate selection lines, information signal lines, and current supply lines, respectively. Pixel circuits are disposed at intersection points of the gate selection lines and the information signal lines. The scanning signal driver sequentially selects the gate selection lines G1, G2, G3, . . . Gn, image signals are applied to the gate selection lines from the information signal driver in synchronization with the selection, and an image is displayed. An example of the driving signals is illustrated in FIG. 5.

A switching device for the present invention is not particularly limited, and any one of a single-crystal silicon substrate, an MIM device, an a-Si type device, and the like can easily be applied thereto.

An organic EL display panel can be obtained by sequentially stacking at least one organic EL layer and a cathode layer on the ITO electrode. The display panel using the organic compound of the present invention can be driven to perform stable display for a long period of time with good image quality.

### EXAMPLES

Hereinafter, the present invention will be described specifically by way of examples. However, the present invention is not limited to those examples.

Hereinafter, synthesis methods necessary for synthesizing the metal complex of the present invention are described in detail by referring to representative synthesis examples.

### Example 1

(Synthesis of Exemplified Compound XB-2)

2-bromopyridine (5 g, 31.6 mmol) and anhydrous diethyl ether (50 ml) were placed in a 100 ml three-necked flask under argon flow. The mixed liquid was cooled to −70° C., a 2.67 mol/L solution of n-BuLi in hexane (11.8 ml, 31.6 mmol) was slowly added to the liquid, and the whole was stirred at the same temperature for 30 minutes. Separately, octafluorocyclopentene (6.7 g, 31.6 mmol) and diethyl ether (100 ml) were added to a 200 ml three-necked flask, and the whole was cooled to −70° C. A solution of 2-lithiated pyridine in the cooled state prepared above was added dropwise to the resultant by using a cannula. After the solution was stirred at the same temperature for 1 hour, a cooling bath was removed, and the temperature of the solution was increased. Distilled water (100 ml) was added to the mixed liquid to separate an organic layer. The aqueous layer was extracted with ethyl acetate (50 ml×twice), and the organic layers were combined, washed with distilled water and saturated brine, and dried with anhydrous magnesium sulfate. After that, the solution was concentrated to give a reddish brown viscous liquid. The liquid was purified by means of silica gel column chromatography (eluent: hexane/ethyl acetate=5:1 to 2:1) to give 0.89 g of Compound XX-1 (10% yield).

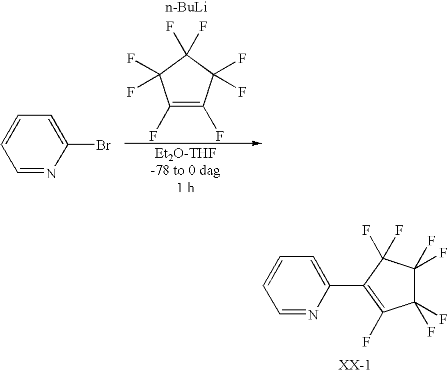

Compound XX-1 (0.89 g, 3.69 mmol), anhydrous methanol (10 ml), and anhydrous tetrahydrofuran (10 ml) were added to a 50 ml three-necked flask. The solution was cooled to −78° C., a 0.2 M solution of NaHBH₄ in EtOH/THF=1/1 (9.22 ml, 1.85 mmol) was slowly added dropwise to the solution, and the whole was stirred at the same temperature for 3 hours. After that, a cooling bath was removed, the temperature of the resultant was increased to 0° C., and distilled water (30 ml) was added to the resultant. The solution was extracted with ethyl acetate (50 ml×twice), and organic layers were combined, washed with distilled water and saturated brine, and dried with anhydrous magnesium sulfate. After that, the solution was concentrated to give a pale yellow liquid. The liquid was purified by distillation to give 0.80 g of Compound XX-2 (86% yield).

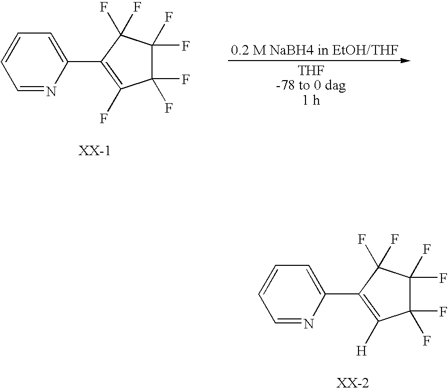

Iridium(III) chloride (30.4 mg, 0.16 mmol), Compound XX-2 (162 mg, 0.64 mmol), and 10 ml of ethoxyethanol were placed in a 20 ml pressure resistant ampoule, and the ampoule was tightly closed in an argon atmosphere. The mixture in the pressure resistant ampoule was stirred with heating at 60° C. for 8 hours. The reaction product was cooled to room temperature, and the solvent was evaporated under reduced pressure. The residue was washed with hexane:diethyl ether=1:1 and vacuum dried to give a yellow powder. 10 ml of ethoxyethanol, 48 mg (0.48 mmol) of acetylacetone, and 85 mg (0.80 mmol) of sodium carbonate were added to the powder, and the whole was stirred at 80° C. for 6 hours.

The reaction liquid was extracted with dichloromethane, and the organic layer was washed with distilled water and saturated brine, and dried with anhydrous magnesium sulfate. After that, the solution was concentrated to give a pale yellow crystal. The crystal was recrystallized from toluene-hexane to give 9 mg of Exemplified Compound XB-2 (7% yield).

By use of a ¹H-NMR spectrum, the structure was identified.

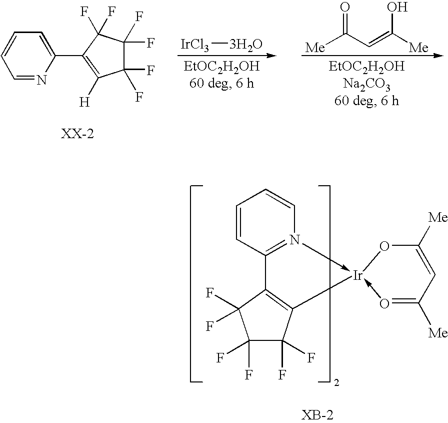

### Example 2

In this example, a device having 3 organic layers such as illustrated in FIG. 2 was used as a device constitution.

ITO (transparent electrode 14) having a thickness of 100 nm was patterned onto a glass substrate (transparent substrate 15) so as to have an opposing electrode area of 3 mm². The following organic layers and electrode layers were sequentially formed on the ITO substrate through vacuum deposition using resistive heating in a vacuum chamber at 10-4 Pa to produce a device.

### Organic Layer 1 (hole-transporting layer 13) (40 nm): α-NPD

### Organic Layer 2 (light-emitting layer 12) (30 nm): CBP:XB-2 (weight ratio 95:5)

### Organic Layer 3 (electron-transporting layer 16) (30 nm): Alq₃

Metal Electrode Layer 1 (15 nm): Al/Li alloy (Li content: 1.8% by weight)

### Metal Electrode Layer 2 (100 nm): Al

When an electric field was applied to the device in such a manner that the ITO side served as an anode and the Al side served as a cathode, light emission was confirmed.

### Example 3

(Synthesis of Exemplified Compound XA-1)

Compound XX-2 (1 g, 3.95 mmol) and Compound XB-2 (0.14 g, 0.173 mmol) were placed in a 10 ml pressure resistant test tube, and the atmosphere in the test tube was replaced with argon. After that, the test tube was tightly closed, and the mixture in the test tube was stirred with heating at or near 190° C. for 1 hour. After the reaction product was cooled to room temperature, Compound XX-2 was evaporated under reduced pressure, and the residue was purified by means of silica gel column chromatography using chloroform as an eluent to give a yellow crystal. The crystal was recrystallized from toluene-hexane to give 24 mg of Exemplified Compound XA-1 (15% yield).

The structure of the compound was identified by a ¹H-NMR spectrum. Further, 949.0 as M+ of the compound was confirmed by means of Matrix Assisted Laser Desorption/Ionization-Time of Flight Mass Spectrometry (MALDI-TOF MS).

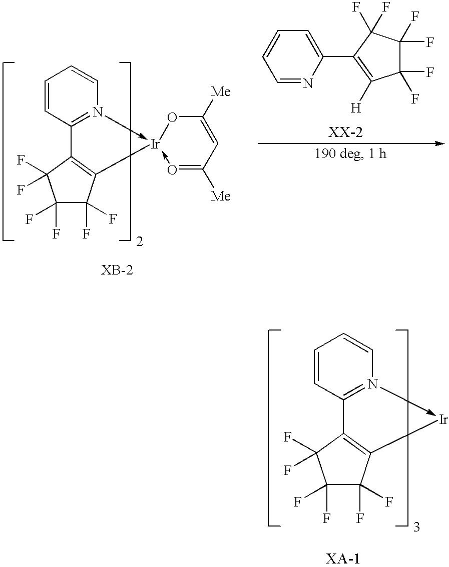

### Example 4

(Synthesis of Exemplified Compound XB-35)

Compound XX-3 (5 g, 50.5 mmol) and anhydrous diethyl ether (50 ml) were placed in a 100-ml three-necked flask under argon flow. The mixed liquid was cooled to −78° C., a 2.67-mol/L solution of n-BuLi in hexane (20.8 ml, 55.5 mmol) was slowly added to the liquid, and the whole was stirred at the same temperature for 30 minutes. Separately, decafluorocyclohexene (14.5 g, 55.5 mmol) and diethyl ether (100 ml) were placed in a 500 ml three-necked flask, and the whole was cooled to −70° C. A solution of 2-lithiated methylthiazol in the cooled state prepared above was added dropwise to the resultant by using a cannula. After the solution was stirred at the same temperature for 1 hour, a cooling bath was removed, and the temperature of the solution was increased. Distilled water (100 ml) was added to the mixed liquid to separate an organic layer. The aqueous layer was extracted with ethyl acetate (200 ml×twice), and the organic layers were combined, washed with distilled water and saturated brine, and dried with anhydrous magnesium sulfate. After that, the solution was concentrated to give a reddish brown viscous liquid. The liquid was distilled to be purified by means of Kugelrohr distillation apparatus to give 4.98 g of Compound XX-4 (29% yield).

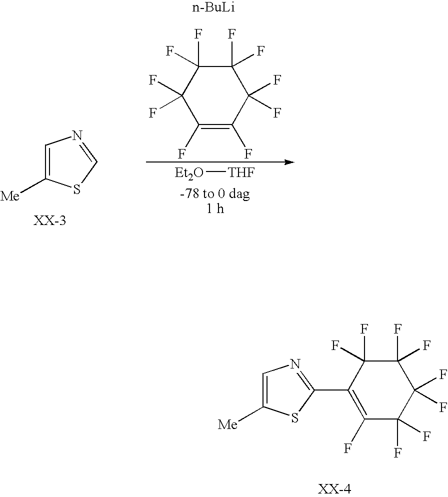

Compound XX-4 (7.76 g, 22.7 mmol), anhydrous ethanol (140 ml), and anhydrous tetrahydrofuran (140 ml) were placed in a 500 ml three-necked flask. The solution was cooled to −78° C., a 0.4 M solution of NaHBH₄ in EtOH/THF=1/1 (28.5 ml, 11.4 mmol) was slowly added dropwise to the solution, and the whole was stirred at the same temperature for 3 hours. After that, a cooling bath was removed, the temperature of the resultant was increased to 0° C., and distilled water (100 ml) was added to the resultant. The solution was extracted with ethyl acetate (150 ml×twice), and the organic layers were combined, washed with distilled water and saturated brine, and dried with anhydrous magnesium sulfate. After that, the solution was concentrated to give a pale yellow liquid. The liquid was purified by distillation to give 5.78 g of Compound XX-5 (79% yield).

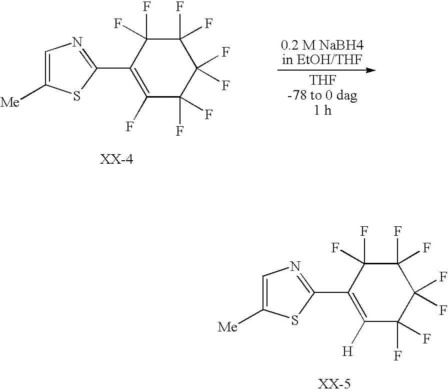

Iridium(III) chloride (30.0 mg, 0.16 mmol), Compound XX-5 (207 mg, 0.64 mmol), and 10 ml of ethoxyethanol were placed in a 20 ml pressure resistant ampoule, and the ampoule was tightly closed in an argon atmosphere. The mixture in the pressure resistant ampoule was stirred with heating at 60° C. for 6 hours. The reaction product was cooled to room temperature, and the solvent was evaporated under reduced pressure. The residue was washed with hexane:diethyl ether 1:1 and vacuum dried to give a yellow powder. 10 ml of ethoxyethanol, 48 mg (0.48 mmol) of acetylacetone, and 85 mg (0.80 mmol) of sodium carbonate were added to the powder, and the whole was stirred at 60° C. for 6 hours.

The reaction liquid was extracted with dichloromethane, and the organic layer was washed with distilled water and saturated brine, and dried with anhydrous magnesium sulfate. After that, the solution was concentrated to give a pale yellow crystal. The crystal was recrystallized from toluene-hexane to give 5 mg of Exemplified Compound XB-35 (3% yield).

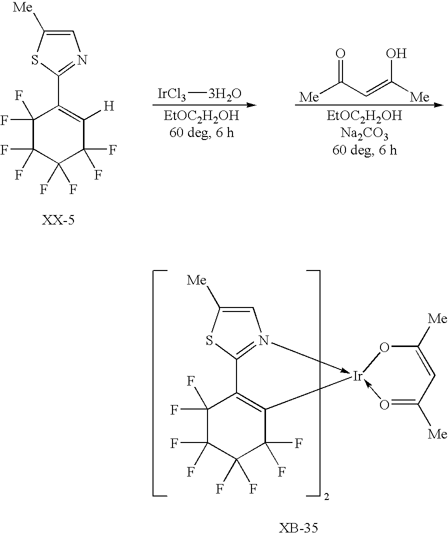

### Example 5

(Synthesis of Exemplified Compound XA-17)

Compound XX-5 (1 g, 3.09 mmol) and Compound XB-35 (0.14 g, 0.16 mmol) were placed in a 10 ml pressure resistant test tube, and the atmosphere in the test tube was replaced by argon. After that, the test tube was tightly closed, and the mixture in the test tube was stirred with heating at or near 190° C. for 1 hour. After the reaction product was cooled to room temperature, Compound XX-5 was distilled under reduced pressure, and the residue was purified by means of silica gel column chromatography using chloroform as an eluent to give a yellow crystal. The crystal was recrystallized from toluene-hexane to give 20 mg of Exemplified Compound XA-17 (11% yield).

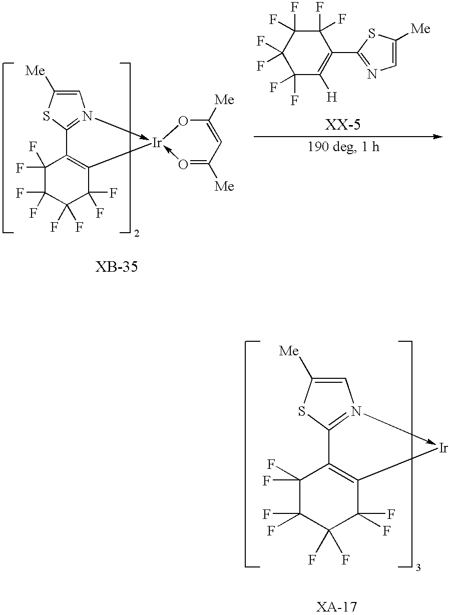

### Example 6

(Synthesis of Exemplified Compound XB-33)

25 g (260 mmol) of cyclohexanone, 500 ml of dry chloroform, and 500 ml of dry pyridine were placed in a 2 L three-necked flask, and the whole was stirred under ice cooling at 0° C. or lower. During the stirring, a solution of 278 g (1.1 mol) of iodine in 500 ml of dry chloroform and 300 ml of dry pyridine was added dropwise to the resultant over about 30 minutes. After that, the temperature of the resultant was increased to room temperature, and then the resultant was stirred for 1 hour. 1,000 ml of water were added to the reaction liquid, and then the whole was extracted with chloroform. The organic layer was washed with 100 ml of water twice, 100 ml of 1N hydrochloric acid twice, 100 ml of water twice, and 100 ml of a saturated aqueous solution of sodium sulfite twice in the stated order, and dried with magnesium sulfate. After that, the solvent was evaporated. The resultant was purified by distillation under reduced pressure to give 41 g of 2-iodocyclohexanone (71% yield).

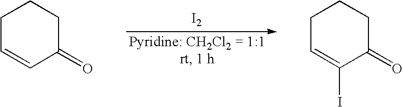

167 mg (0.75 mmol) of 2-iodocyclohexanone, dichloromethane (0.5 ml), and 158 mg (0.9 mmol) of N-trifluorosulfurmorpholine are placed in a vessel for a high-pressure reaction made of Teflon™, and the whole is stirred with heating under 10,000 atm at 40° C. for 72 hours. The resultant is cooled to room temperature, the pressure is returned to atmospheric pressure, an aqueous solution of sodium hydrogen carbonate is added to the resultant, and the whole is extracted with dichloromethane. The organic layer is washed with saturated brine and dried with magnesium sulfate. After that, the resultant is filtrated through a funnel containing a thin layer of silica gel, and the solvent is evaporated. The residue is purified by means of flash column chromatography (eluent: 3% chloroform/petroleum ether), whereby 6,6-difluoro-1-iodocyclohexene can be synthesized.

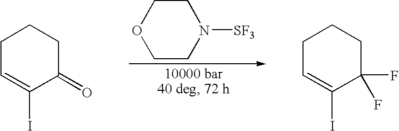

1.8 g (7.5 mmol) of 6,6-difluoro-1-iodocyclohexene, 2.4 g (9.8 mmol) of 2-trimethyltinpyridine, 182 mg (0.26 mmol) of dichlorodi(triphenylphosphine)palladium, 415 mg (9.8 mmol) of lithium chloride, and 50 ml of toluene are placed in a 200 ml round bottom flask, and the whole is heated to reflux with stirring under nitrogen flow for 18 hours. The reaction solution is poured into 100 ml of cold water, and the whole is extracted with toluene. After having been washed with saturated brine, the organic layer is dried with magnesium sulfate, and the solvent is evaporated. The residue is purified with a silica gel column (eluent: toluene), whereby 6,6-difluoro-1-(2-pyridyl)cyclohexene can be synthesized.

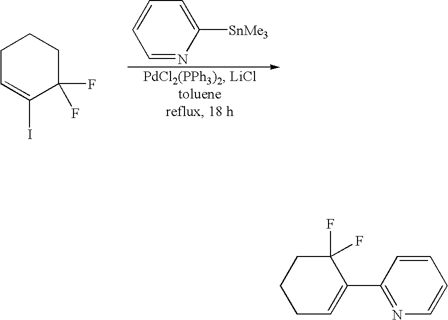

0.60 g (1.70 mmol) of iridium(III) chloride, 1.48 g (7.58 mmol) of 6,6-difluoro-1-(2-pyridyl)cyclohexene, 50 ml of ethoxyethanol, and 20 ml of water are placed in a 200 ml three-necked flask, and the whole is stirred under nitrogen flow at room temperature for 30 minutes. After that, the resultant is stirred for 24 hours at 80° C. The reaction product is cooled to room temperature, and the precipitate is isolated by filtration and washed with water. After that, the precipitate is washed with ethanol and acetone sequentially. The resultant is dried at room temperature under reduced pressure, whereby tetrakis[6,6-difluoro-1-(2-pyridyl)cyclohexene-N,C2] (μ-dichloro)diiridium(III) can be synthesized.

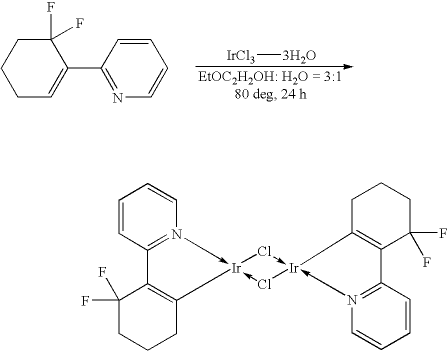

70 ml of ethoxyethanol, 0.53 g (0.63 mmol) of tetrakis[6,6-difluoro-1-(2-pyridyl)cyclohexene-N,C2](μ-dichloro)diiridium(III), 188 mg (1.88 mmol) of acetylacetone, and 1.00 g (9.45 mmol) of sodium carbonate are placed in a 200 ml three-necked flask, and the whole is stirred under nitrogen flow at room temperature. After that, the resultant is refluxed with stirring for 15 hours. The reactant is cooled with ice, and the precipitate is isolated by filtration and washed with water. The precipitate is purified by means of silica gel column chromatography (eluent: chloroform/methanol=30/1), whereby bis[6,6-difluoro-1-pyridylhexene-N,C2](acetylacetonato)iridium(III) (Exemplified Compound XB-33) can be synthesized.

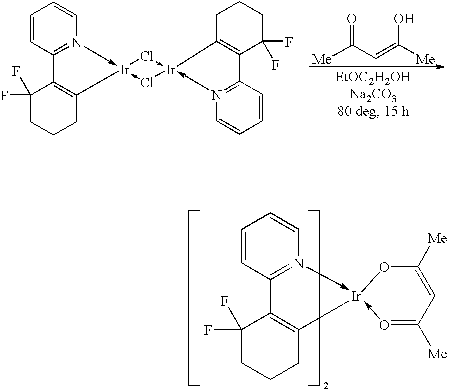

### Example 7

(Synthesis of Exemplified Compound XA-7)

0.37 g (1.89 mmol) of 6,6-difluoro-1-(2-pyridyl)cyclohexene, 0.44 g (0.63 mmol) of bis[6,6-difluoro-1-(2-pyridyl)cyclohexene-N,C2](acetylacetonato)iridium(III), and 50 ml of glycerol are placed in a 200 ml three-necked flask, and the whole is stirred with heating under nitrogen flow at or near 190° C. for 1 hour. The reaction product is cooled to room temperature, and 6,6-difluoro-1-(2-pyridyl)cyclohexene is evaporated. The residue is purified by means of silica gel column chromatography using chloroform as an eluent, whereby tris[1-(2-pyridyl)cyclopentene-N,C2]iridium(III) (Exemplified Compound XA-7) can be synthesized.

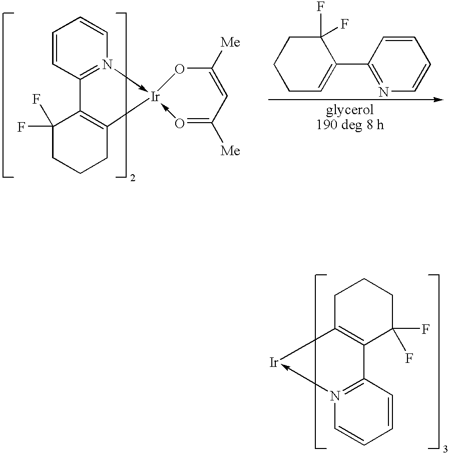

### Example 8

(Synthesis of Exemplified Compound XA-7)

1 g (5.12 mmol) of 6,6-difluoro-1-(2-pyridyl)cyclohexene and 0.1 g (0.17 mmol) of bis[2-phenylpyridine-N,C2](acetylacetonato)iridium(III) are placed in a 10 ml pressure resistant test tube, and the atmosphere in the test tube is replaced by argon. After that, the test tube is tightly closed, and the mixture in the test tube is stirred with heating at or near 190° C. for 8 hours. After the reaction product has been cooled to room temperature, 6,6-difluoro-1-(2-pyridyl)cyclohexene is distilled under reduced pressure, and the residue is purified by means of silica gel column chromatography using chloroform as an eluent, whereby tris[1-(2-pyridyl)cyclopentene-N,C2]iridium(III) (Exemplified Compound XA-7) can be synthesized.

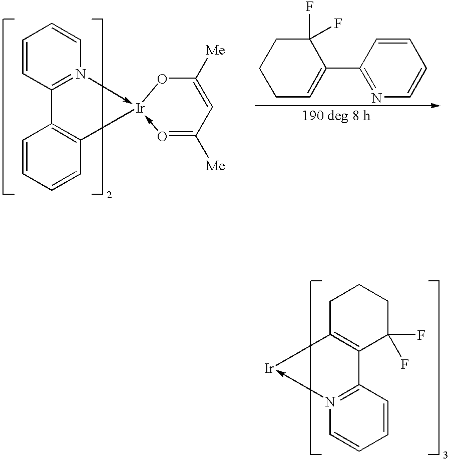

### Example 9

(Synthesis of Exemplified Compound XC-13)

2.40 g (6.81 mmol) of iridium(III) chloride, 1.33 g (6.80 mmol) of 6,6-difluoro-1-(2-pyridyl)cyclohexene, and 100 ml of ethoxyethanol are placed in a 200 ml three-necked flask, and the whole is stirred under nitrogen flow at room temperature for 30 minutes. After that, the resultant is stirred for 18 hours at 80° C. The reaction product is cooled to room temperature, and the precipitate is isolated by filtration and washed with water. After that, the precipitate is washed with ethanol and acetone sequentially. The precipitate, 100 ml of ethoxyethanol, 4.09 g (40.9 mmol) of acetylacetone, and 7.22 g (68.1 mmol) of sodium carbonate are placed in a 200 ml three-necked flask, and the whole is stirred under nitrogen flow at room temperature. After that, the resultant is stirred for 18 hours at 80° C. The reaction product is cooled with ice, and the reaction liquid is evaporation. The residue is purified by means of silica gel column chromatography (eluent: chloroform/ethyl acetate=2/1), whereby bis(acetylacetonato)[6,6-difluoro-1-pyridylhexene-N,C2]iridium(III) (Exemplified Compound XC-13) can be synthesized.

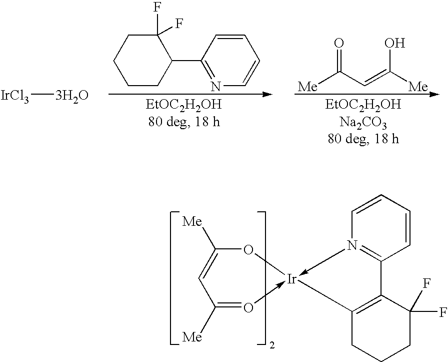

### Example 10

(Synthesis of Exemplified Compound XB-12)

Exemplified Compound XB-12 can be synthesized by following the same procedure as in Example 1 with the exception that 2-bromo-4-(N,N-dimethylamino)pyridine is used instead of 2-bromopyridine.

### Example 11

(Synthesis of Exemplified Compound XA-44)

Exemplified Compound XA-44 can be synthesized by following the same procedure as in Example 3 with the exception that Compound XX-6 is used instead of Compound XX-2 and Compound XB-12 is used instead of Compound XB-2.

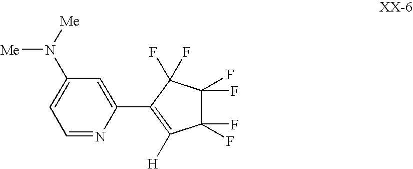

### Example 12

Synthesis of Exemplified Compound XB-14

Exemplified Compound XB-14 can be synthesized by following the same procedure as in Example 1 with the exception that 2-bromo-4-methoxypyridine is used instead of 2-bromopyridine.

### Example 13

(Synthesis of Exemplified Compound XA-46)

Exemplified Compound XA-46 can be synthesized by following the same procedure as in Example 3 with the exception that Compound XX-7 is used instead of Compound XX-2 and Compound XB-14 is used instead of Compound XB-2.

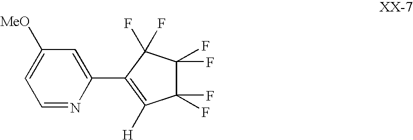

### Example 14

(Synthesis of Exemplified Compound XC-16)

Exemplified Compound XC-16 can be synthesized by following the same procedure as in Example 8 with the exception that Compound XX-2 is used instead of 6,6-difluoro-1-(2-pyridyl)cyclohexene and picolinic acid is used instead of acetylacetone.

### Example 15

(Synthesis of Exemplified Compound XB-38)

Exemplified Compound XB-38 can be synthesized by following the same procedure as in Example 4 with the exception that N-methyl-3-bromopyrazole is used instead of Compound XX-3.

### Example 16

(Synthesis of Exemplified Compound XA-18)

Exemplified Compound XA-18 can be synthesized by following the same procedure as in Example 3 with the exception that Compound XX-8 is used instead of Compound XX-2 and Compound XB-38 is used instead of Compound XB-2.

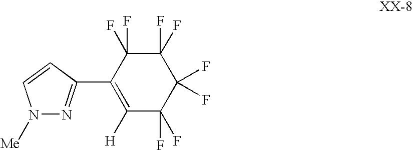

The metal complex of the present invention having, in a molecule thereof, a non-aromatic ring structure containing at least one olefin and at least one F atom, and an unsaturated heterocyclic ring structure containing at least one nitrogen atom can be utilized in a light-emitting device to provide excellent emission efficiency. In addition, the light-emitting device of the present invention can be utilized as a display device.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application 2006-129296, filed on May 8, 2006, which is hereby incorporated by reference herein in its entirety.

What is claimed is:

1. A metal complex comprising a partial structure represented by the general formula (1): 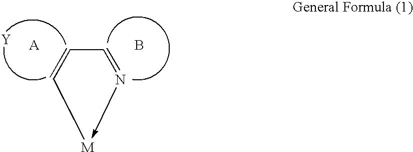
wherein a ring structure A is a non-aromatic cyclic group which comprises a carbon atom bonded to M and at least one olefin structure and may have a substituent;
Y represents an alkylene group which comprises 2 to 6 carbon atoms and at least one F atom in which one methylene group or two non-adjacent methylene groups of the alkylene group may be replaced by —O—, —CO—, —CO—O—, —O—CO—, —S—, —CR₁═CR₂—, or —NR₃— where R₁, R₂, and R₃ may each be substituted with a hydrogen atom, a linear or branched alkyl group having 1 to 10 carbon atoms in which a hydrogen atom of the alkyl group may be substituted with a fluorine atom, and in which a hydrogen atom of the alkylene group may be substituted with a linear or branched alkyl group having 1 to 10 carbon atoms in which a hydrogen atom of the alkyl group may be substituted with a fluorine atom, or with a fluorine atom;
a ring B is a cyclic group which has a nitrogen atom bonded to M and may have a substituent selected from a halogen atom, a nitro group, an aromatic ring group which may have a substituent selected from a halogen atom, or a linear or branched alkyl group having 1 to 20 carbon atoms in which one methylene group or two or more non-adjacent methylene groups of the alkyl group may each be replaced by —O—, —S—, —CO—, —CO—O—, —O—CO—, —CH═CH—, or —C≡C— and in which a hydrogen atom of the alkyl group may be substituted with a fluorine atom, a disubstituted amino group, a trialkylsilyl group having 1 to 8 carbon atoms, or a linear or branched alkyl group having 1 to 20 carbon atoms in which one methylene group or two or more non-adjacent methylene groups of the alkyl group may each be replaced by —O—, —S—, —CO—, —CO—O—, —O—CO—, —CH═CH—, or —C≡C—, and in which a hydrogen atom of the alkyl group may be substituted with a fluorine atom; and
M represents Ir, Pt, Rh, or Ru.

2. The metal complex according to claim 1, which comprises a partial structure represented by the general formula (2):
MLₘL′ₙ (2)
wherein L and L′ represent bidentate ligands different from each other, m represents 1, 2, or 3, n represents 0, 1, or 2 with the proviso that m+n represents 2 or 3, a partial structure MLₘ is represented by the general formula (3), and a partial structure ML′ₙ is represented by the general formula (4), (5), or (6): 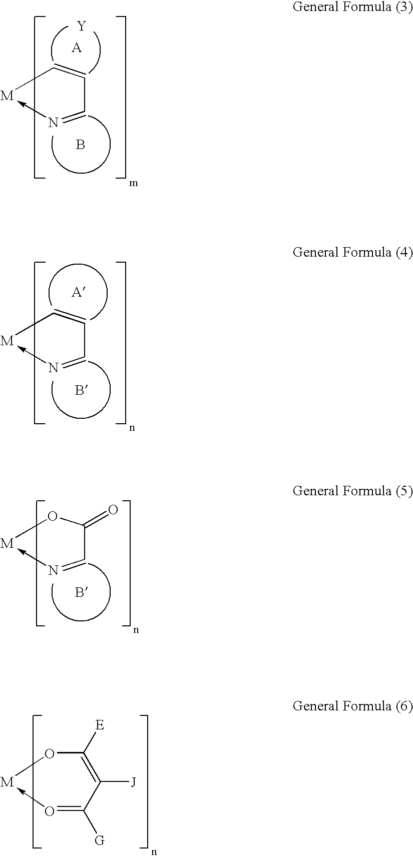
A, B, and Y are each as defined above for the general formula (1);
N represents a nitrogen atom, A′ represents a cyclic group which is bonded to a metal atom M through a carbon atom and may have a substituent, B′ represents a cyclic group which is bonded to the metal atom M through a nitrogen atom and may have a substituent, and A′ and B′ are covalently bonded;
E and G each represent a linear or branched alkyl group having 1 to 20 carbon atoms in which one methylene group or two or more non-adjacent methylene groups of the alkyl group may each be replaced by —O—, —S—, —CO—, —CO—O—, —O—CO—, —CH═CH—, or —C≡C— and in which a hydrogen atom of the alkyl group may be replaced by a fluorine atom, or an aromatic ring group which may have a substituent selected from a halogen atom, a cyano group, a nitro group, a trialkylsilyl group in which the alkyl groups are each independently a linear or branched alkyl group having 1 to 8 carbon atoms, or a linear or branched alkyl group having 1 to 20 carbon atoms in which one methylene group or two or more non-adjacent methylene groups of the alkyl group may each be replaced by —O—, —S—, —CO—, —CO—O—, —O—CO—, —CH═CH—, or —C≡C— and in which a hydrogen atom of the alkyl group may be substituted with a fluorine atom;
J represents a hydrogen atom, a halogen atom, a linear or branched alkyl group having 1 to 20 carbon atoms in which one methylene group or two or more non-adjacent methylene groups may each be replaced by —O—, —S—, —CO—, —CO—O—, —O—CO—, —CH═CH—, or —C≡C— and in which a hydrogen atom of the alkyl group may be substituted with a fluorine atom, or an aromatic ring group which may have a substituent selected from a halogen atom, a cyano group, a nitro group, a trialkylsilyl group in which the alkyl groups are each independently a linear or branched alkyl group having 1 to 8 carbon atoms, or a linear or branched alkyl group having 1 to 20 carbon atoms in which one methylene group or two or more non-adjacent methylene groups may each be replaced by —O—, —S—, —CO—, —CO—O—, —O—CO—, —CH═CH—, or —C≡C— and in which a hydrogen atom of the alkyl group may be substituted with a fluorine atom; and
M represents Ir, Pt, Rh, or Ru.

3. The metal complex according to claim 1, wherein M represents Ir.

4. A light-emitting device comprising at least one organic compound layer including a layer containing the metal complex set forth in claim 1.

5. The light-emitting device according to claim 4, wherein the layer containing the metal complex is a light-emitting layer.

6. The light-emitting device according to claim 4, wherein the layer containing the metal complex is a hole-transporting layer.

7. The light-emitting device according to claim 4, wherein the layer containing the metal complex is an electron-transporting layer.

8. The light-emitting device according to claim 5, wherein the light-emitting layer contains a plurality of phosphorescent materials.

9. An organic light-emitting device comprising:
two opposing electrodes; and
the layer containing the metal complex set forth in claim 4 interposed between the two opposing electrodes, wherein light is emitted by applying a voltage between the electrodes.

10. An image display apparatus comprising:
the organic light-emitting device set forth in claim 9; and
a unit for supplying an electrical signal to the organic light-emitting device.
